(19) United States
(12) Patent Application Publication
(10) Pub. No.: US 2008/0171422 A1
(43) Pub. Date: Jul. 17, 2008

(54) APPARATUS AND METHODS FOR FABRICATION OF THIN FILM ELECTRONIC DEVICES AND CIRCUITS

(76) Inventors: Jeffrey H. Tokie, Scandia, MN (US); Donald J. McClure, Shoreview, MN (US); Daniel H. Carlson, Arden Hills, MN (US); James N. Dobbs, Woodbury, MN (US); John T. Strand, Stillwater, MN (US); Ronald P. Swanson, Woodbury, MN (US)

Correspondence Address: 3M INNOVATIVE PROPERTIES COMPANY, PO BOX 33427, ST. PAUL, MN, 55133-3427, US

(21) Appl. No.: 11/622,209

(22) Filed: Jan. 11, 2007

(51) Int. Cl. H01L 21/20; H01L 21/36

(52) U.S. Cl. 438/479

(57) ABSTRACT

Methods and systems for forming layered electronic devices on a flexible, elongated substrate are described. The layered electronic devices include at least one electronically or optically active layer. Deposition of one more layers of the electronic devices occurs as the flexible substrate is moved through one or more deposition stations. At each deposition station the substrate is aligned with an aperture mask having apertures arranged in a pattern. The aperture mask and the substrate are brought into proximity over a portion of a circumference of a rotating drum. A layer of the layered electronic devices is formed by deposition of material through the apertures of the aperture mask. At each deposition station, registration between at least two layers of the layered electronic devices is maintained.

### TECHNICAL FIELD

The present invention is related to formation of electronic devices and/or circuits. More particularly, the present invention is related to fabrication of electronic devices by deposition of material through an aperture mask.

### BACKGROUND

Patterns of material may be formed on a substrate by emitting material from a deposition source in a direction toward the substrate. The material is deposited in a particular pattern onto the substrate by having a mask located between the deposition source and the substrate. The mask includes apertures that define the pattern, and only the deposition material passing through the apertures reaches the substrate so that the material is deposited in a pattern.

Electronic devices may be formed as layered structures on a substrate. Patterns of material may be deposited in layers through multiple deposition steps to form the layered electronic devices. The devices may be connected into circuits via deposition of conductive traces.

Conventional patterned deposition of material through a mask onto a roll of substrate material is done in a step and repeat fashion. The substrate moves forward by a pre-defined amount and stops with the mask being in a fixed and known position relative to the substrate. Then, the deposition source emits the material through the mask to form the pattern. The substrate then moves again by a pre-defined amount and stops and the deposition occurs again. This is repeated to form multiple instances of a given pattern of material onto a roll of substrate material. Each pattern of material on the substrate may be exposed to another downstream mask and deposition source to form additional layers of patterned material.

The step and repeat procedure, while effective at accurately producing multiple instances of the pattern with a relatively fine feature size, has the drawback of being relatively inefficient. The time spent moving the substrate and precisely aligning the mask and substrate, which is a significant amount of time relative to the total time to deposit the layer, is time spent not depositing material. Therefore, the step and repeat procedure may not achieve a rate of production that is desirable.

### SUMMARY

One embodiment of the invention involves a method of forming one or more electronic devices having multiple overlapping layers on a flexible, elongated substrate. The method includes moving the flexible substrate through one or more deposition stations. At each deposition station, an elongated aperture mask is moved in relation to a rotating drum, the aperture mask having apertures arranged in a pattern. The aperture mask and the substrate are aligned and are brought into proximity over a portion of a circumference of the rotating drum. A layer of the layered electronic devices is deposited through the apertures of the aperture mask. Registration is maintained between at least two layers of the layered electronic devices. At least one layer of the layered electronic devices comprises an electronically or optically active material.

Another embodiment of the invention is directed to an apparatus for forming one or more electronic devices having multiple overlapping layers on a flexible, elongated substrate. The apparatus includes one or more deposition stations. Each deposition station includes an elongated aperture mask having apertures arranged in a pattern, a rotating drum, and a deposition source positioned relative to the rotating drum. The deposition source is configured to emit material toward the substrate through the apertures of the aperture mask to form a layer of the layered electronic devices. A transport system is configured to move the substrate through the one or more deposition stations. At each deposition station, the substrate comes into proximity with the aperture mask of the deposition station over a portion of the circumference of the drum. An alignment system is configured to maintain registration between at least two layers of the layered electronic devices. At least one layer of the layered electronic devices comprises an electronically or optically active material.

The above summary of the present invention is not intended to describe each embodiment or every implementation of the present invention. Advantages and attainments, together with a more complete understanding of the invention, will become apparent and appreciated by referring to the following detailed description and claims taken in conjunction with the accompanying drawings.

### DESCRIPTION OF THE DRAWINGS

FIG. 1 is a diagram illustrating a method of fabricating layered electronic devices in accordance with embodiments of the invention;

FIG. 2 illustrates a deposition system having a plurality of deposition stations 1 to N that may be used to implement the fabrication methods in accordance with embodiments of the invention;

FIGS. 3A-3D are cross sectional views of thin film transistors (TFTs) that may be fabricated in accordance with embodiments of the invention;

FIG. 4 depicts a cross sectional view of a photovoltaic cell that may be fabricated in accordance with embodiments of the invention;

FIG. 5 illustrates a Schottky diode that may be fabricated in accordance with embodiments of the invention;

FIGS. 6A-6D illustrate various configurations of LED devices incorporating an organic active layer (OLEDs) that may be formed using the fabrication processes in accordance with embodiments of the invention;

FIG. 6E illustrates a configuration of a pixel TFT and organic light emitting diode (OLED) on a common substrate that may be formed using the fabrication processes in accordance with embodiments of the invention;

FIG. 7 shows an embodiment of an apparatus providing a first stage of a deposition process with an internal drum deposition, without pre-patterned fiducial elements, and with a roll-to-roll mask;

FIG. 8 shows an embodiment of an apparatus providing a first stage of a deposition process with an internal drum deposition, without pre-patterned fiducial elements, and with a continuous-loop mask;

FIG. 9 shows an embodiment of an apparatus providing a first stage of a deposition process with an external drum deposition, without pre-patterned fiducial elements, and with a roll-to-roll mask;

FIG. 10 shows an embodiment of an apparatus providing a first stage of a deposition process with an internal drum deposition, with pre-patterned fiducial elements, and with a roll-to-roll mask;

FIG. 11 shows an embodiment of an apparatus providing a first stage of a deposition process with an external drum deposition, without pre-patterned fiducial elements but with the fiducial patterning occurring in advance of the external drum deposition, and with a roll-to-roll mask;

FIG. 12 shows an embodiment of an apparatus providing a second stage of a deposition process with an internal deposition, and with a roll-to-roll mask;

FIG. 13 shows an illustrative rotary motor and velocity/position control system schematic for controlling the longitudinal web position for various embodiments.

FIG. 14 shows an illustrative guide motor control system schematic for controlling the lateral web position for various embodiments;

FIG. 15 shows a web fiducial registration control system schematic for maintaining proper registration of the two webs for various embodiments;

FIG. 16 shows an illustrative control system interface for the fiducial registration sensors of an embodiment of an apparatus providing a second stage of a deposition process;

FIG. 17 shows a control loop utilized by the illustrative control system interface of FIG. 16;

FIG. 18 shows an illustrative pattern of fiducial elements utilized on the mask and/or substrate for sensing both the relative lateral and longitudinal positions of each;

FIG. 19A shows a view of an illustrative sensing system for sensing both the lateral and longitudinal web position; and

FIGS. 19B-19D show examples of fiducial marks within the image view of sensors of various types in accordance with embodiments of the invention.

While the invention is amenable to various modifications and alternative forms, specifics thereof have been shown by way of example in the drawings and will be described in detail. It is to be understood, however, that the intention is not to limit the invention to the particular embodiments described. On the contrary, the intention is to cover all modifications, equivalents, and alternatives falling within the scope of the invention as defined by the appended claims.

### DETAILED DESCRIPTION

In the following description of the illustrated embodiments, reference is made to the accompanying drawings which form a part hereof, and in which are shown by way of illustration, various embodiments in which the invention may be practiced. It is to be understood that the embodiments may be utilized and structural changes may be made without departing from the scope of the present invention.

Embodiments of the present invention are directed to methods and systems for fabrication of layered electronic devices on a flexible substrate. The use of thin layers on a flexible substrate allows for roll to roll fabrication of the layered electronic devices. The embodiments described herein advantageously provide for high speed fabrication of small feature layered electronic devices including thin film transistors, diodes, light emitting diodes, and/or other electronic devices. The deposition techniques described can be used to create layered electronic devices on a flexible web substrate in which the achievable feature size may be on the order of several microns, ranging down to about 2 microns. At least two layers of the layered electronic devices are maintained in proper registration to within a tolerance of ½ of the smallest feature dimension. For example, the feature size may be less than about 100 microns and the registration tolerance may be less than about 50 microns.

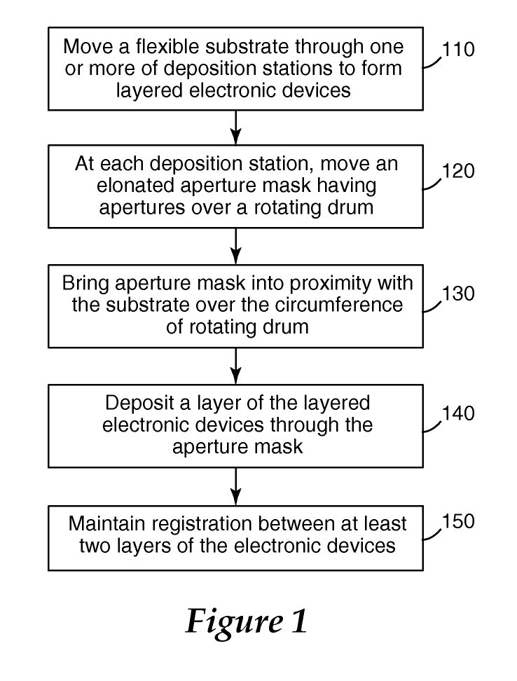

FIG. 1 is a diagram illustrating a method of fabricating layered electronic devices in accordance with embodiments of the invention. The fabrication method involves moving 110 a flexible substrate through one or more deposition stations to form one or more electronic devices that have a plurality of overlapping layers. At least one of the electronic device layers is an electronically or optically active material. At each deposition station of the one or more deposition stations, an aperture mask having apertures moves 120 over a rotating drum. The flexible substrate and the aperture mask are brought 130 in proximity over a portion of a circumference of the rotating drum. Material is emitted from a deposition source towards the substrate and is deposited 140 through the apertures of the aperture mask to form a layer of the electronic device. Registration is maintained 150 between at least two layers of the electronic devices during the deposition.

The one or more layered electronic devices formed by the process include an electronically or optically active material, such as an organic or inorganic semiconductor, which may be deposited at one or more of the deposition stations. At other depositions stations, material that provides an electrical contact to the electronically or optically active material may be deposited. At yet other deposition stations material forming additional electronic device layers, e.g., dielectric material, hole or electron transport material, doped buffer material, or connections between devices may be deposited.

Electronic device layers are in registration when a layer is sufficiently aligned with previously deposited layers to achieve a functioning electronic device. Differing layers may tolerate different levels of mis-registration. In general, the better the registration precision, the smaller the feature sizes that can be made. The feature sizes achievable using the methods and systems of the present invention may be on the order of several microns. Registration between the electronic device layers may be maintained to ½ the smallest feature size.

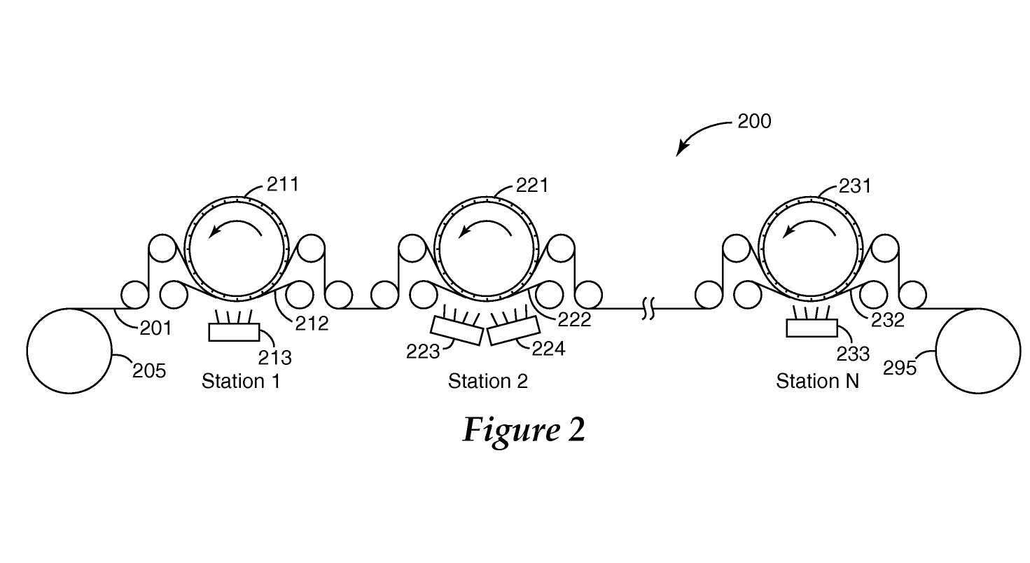

Approaches of the present invention may be implemented by a deposition system having one or more deposition stations. For example, in one configuration, a deposition system, such as the one illustrated in FIG. 2, may deposit a number of the device layers, maintaining registration between at least two of the layers. In another configuration, the deposition system may comprise only one deposition station that deposits a single electronic device layer and maintains registration between the single layer and one or more previously deposited layers. For example, one or more first layers of the electronic devices may be previously formed or deposited by another process such as photolithography or ink jet printing. A deposition system having one deposition station implementing processes in accordance with the invention may deposit a subsequent layer maintaining registration between the subsequent layer and at least one of the previously deposited layers.

FIG. 2 illustrates a deposition system 200 having a plurality of deposition stations 1 to N that may be used to implement the fabrication methods described herein. As previously discussed, in other embodiments, only one deposition station is used. The deposition system of FIG. 2 includes a transport system configured to move the substrate 201 through the plurality of deposition stations 1 to N and to move the aperture masks 212, 222, 232 in relation to the rotating drums 211, 221, 231 at each station 1 to N. The transport system may be configured to maintain a predetermined elongation of the aperture masks 212, 222, 232 or the substrate 201.

In one embodiment, the flexible substrate 201 is delivered via an unwind wheel 205. The substrate 201 is transported through the plurality of deposition stations 1 to N, gaining successive electronic device layers as the substrate 201 passes through the deposition stations 1 to N. Each deposition station includes at least one rotating drum 211, 221, 231, at least one aperture mask 212, 222, 232, and at least one deposition source 213, 223, 233. Some deposition stations, such as Station 2, may include multiple deposition sources 223, 224 that are used to simultaneously or sequentially deposit separate device layers through the aperture mask 222.

At each deposition station 210, 220, 230, the flexible substrate 201 and the aperture mask 212, 222, 232 are brought in proximity over a circumference of the surface of the drum 211, 221, 231. The flexible substrate 201 and the aperture mask 212, 222, 232 may or may not make contact as they are brought in proximity.

Deposition material is emitted from the deposition sources 213, 223, 224 233 towards the substrate 201 and is deposited through the apertures of the aperture mask 212, 222, 232 to form successive electronic device layers.

In some implementations, the aperture pattern in the aperture mask 212, 222, 232 may be formed so that the pattern compensates for tension placed on the mask during the manufacturing processes described herein. The untensioned aperture mask pattern may be adjusted to compensate for the contraction and/or distortion of the mask pattern under operating tension so that during operation of the system, the desired mask pattern is achieved. For example, in some configurations, the mask 212, 222, 232 is held in tension in the longitudinal direction and is not tensioned, or not tensioned an equal amount, in the lateral direction. In these configurations, the flexible mask 212, 222, 232 stretches longitudinally causing distortion of the apertures initially formed in the mask 212, 222, 232. For example, a circular aperture may distort to become an ellipse having its major axis in the longitudinal direction when the mask 212, 222, 232 is tensioned longitudinally. To compensate for this distortion caused by tensioning of the mask 212, 222, 232, the apertures may be “pre-distorted” by initially forming the aperture as an ellipse having the major dimension in the lateral direction. Subsequent application of tension to the mask 212, 222, 232 in the longitudinal direction produces a circular aperture.

An alignment system is configured to align one or more aperture masks 212, 222, 232 and the substrate 201 and to maintain registration between layers of the layered electronic devices. For example, the alignment system may use fiducial marks on the aperture masks 212, 222, 232 and/or the substrate 201 for determining the position of an aperture mask or substrate. Other types of alignment techniques are also possible, such as through the use of rotational encoders and web tensioning mechanisms of the substrate and/or aperture mask transport system to determine the speed and/or position of the substrate and/or aperture masks. After exiting the last deposition station, the flexible substrate 201, having the layered electronic devices deposited thereon, may be wound on a wind wheel 295.

Various types of layered electronic and/or optoelectronic devices and subsystems, including thin film transistors (TFTs), photovoltaic (PV) devices, Schottky diodes, and organic light emitting diodes (OLEDs) may be fabricated using the methods and systems described herein. Stacked layered devices, e.g., OLEDs stacked on TFTs may also be formed. In an example described in more detail below, stacked OLEDs and TFTs form a display backplane that may be fabricated using the techniques described herein.

The layered electronic devices formed in accordance with various embodiments described herein include an active layer, such as an electronically or optically active semiconductor layer. The active layer is typically deposited by the deposition system, but need not be. Ohmic or rectifying contacts to the active layer may be formed by deposition of conductive materials that make direct or indirect contact with the active layer materials. In general, contact to the active layer may be made by metallic or conductive metal oxide materials comprising materials such as silver, gold, aluminum, copper, indium tin oxide, and/or other materials. The conductive materials may comprise organic conductors, such as poly(3,4-ethylenedioxythiophene) (PEDOT). Various other suitable conductive materials may be used. Before, during or after formation of the layered electronic devices, patterns of conductive materials may be deposited to make circuit connections between two or more of the electronic devices formed on the substrate.

The active layer may comprise one or more doped or undoped semiconductor materials. Inorganic semiconductors, such as amorphous or crystalline inorganic semiconductors may be used to form an active layer of the electronic devices. For example, non-limiting exemplary materials that may be used include amorphous silicon, zinc oxide, and other II-VI compounds and their alloys and mixtures, InZnO and InGaZnO. Various other suitable electronically or optically active inorganic semiconductors known in the art may be used to form the multilayer electronic devices in accordance with embodiments of the invention.

Organic semiconductors may be used to form the active layer of the electronic devices. For example, a variety of organic semiconductor materials may be used including fused aromatic ring compounds as exemplified by small molecules such as pentacene-containing compounds, tetracene-containing compounds, anthracene-containing compounds, bis(acenyl)acetylene compounds, and acene-thiophene compounds. Several polymeric materials have also been considered such as regioregular polythiophenes exemplified by poly(3-alkylthiophene) and polymers having fused thiophene units or bis-thiophene units.

Copolymeric materials may be used to form the active layer. More specifically, acene-thiophene copolymers with attached silylethynyl groups can be used in one or more layers in electronic devices such as organic thin film transistors, light emitting diodes, and photovoltaic cells.

The formation of Schottky diodes involves selection of materials to achieve appropriate energy band relationships between the rectifying and ohmic contacts and the semiconductor active layer. One organic compound that is particularly useful as the active layer of Schottky diodes is pentacene, a π-conjugated molecule. Recently Schottky diodes utilizing a doped buffer layer, for example, between the ohmic contact and the active layer, have been described. In one implementation, 4,4′,4″-tris (3-methylphenylphenyl amino) triphenylamine (MTDATA) may be used to make the buffer layer if the organic semiconductor layer is a p-type material. MTDATA is a stable amorphous glass that functions as a hole transport material for organic light-emitting diodes. The layer of MTDATA is doped to greatly increase its conductivity. MTDATA may be doped by co-subliming it with acceptor molecules of the fluorinated form of tetracyanoquinodimethane (F₄-TCNQ). Doping concentrations of 3-20% F₄-TCNQ in MTDATA are effective, with doping concentrations of about 5% to about 10% F₄-TCNQ in MTDATA providing best results.

The devices may include hole or electron transport layers. Hole transport layers facilitate the injection of holes into the device and their migration towards the recombination zone and/or may act as a barrier for the passage of electrons. In some examples, the acene-thiophene copolymer can be used in the hole transport layer. In other examples, the hole transport layer can include, for example, a diamine derivative, such as N,N′-bis(3-methylphenyl)-N,N′-bis(phenyl)benzidine (TPD), N,N′-bis(2-naphthyl)-N,N′-bis(phenyl)benzidine (beta-NPB), and N,N′-bis(1-naphthyl)-N,N′-bis(phenyl)benzidine (NPB); or a triarylamine derivative, such as, 4,4′,4″-tris(N,N-diphenylamino)triphenylamine (TDATA), 4,4′,4″-tris(N-3-methylphenyl-N-phenylamino)triphenylamine (MTDATA), 4,4′,4″-tri(N-phenoxazinyl) triphenylamine (TPOTA), and 1,3,5-tris(4-diphenylaminophenyl)benzene (TDAPB).

Electron transport layers facilitate the injection of electrons into the device and their migration towards the recombination zone of the device and/or may further act as a barrier for the passage of holes. In some examples, the electron transport layer 40 can be formed using the organometallic compound such as tris(8-hydroxyquinolato) aluminum (Alq3) and biphenylato bis(8-hydroxyquinolato)aluminum (BAlq). Other examples of electron transport materials useful in electron transport layer 260 include 1,3-bis[5-(4-(1,1-dimethylethyl)phenyl)-1,3,4-oxadiazol-2-yl]benzene; 2-(biphenyl-4-yl)-5-(4-(1,1-dimethylethyl)phenyl)-1,3,4-oxadiazole; 9,10-di(2-naphthyl)anthracene (ADN); 2-(4-biphenyl)-5-(4-t-butylphenyl)-1,3,4-oxadiazole; or 3-(4-biphenylyl)-4-phenyl-5-(4-tert-butylphenyl)-1,2,4-triazole (TAZ).

Materials and structures useful in the formation of TFTs, PV devices, and OLEDs are further described in commonly owned U.S. patent application Ser. No. 11/379,643, filed Apr. 21, 2006 and U.S. patent application Ser. No. 11/379,662 filed Apr. 21, 2006 which are incorporated herein by reference. Materials and structures useful in the formation of Schottky diodes are described in commonly owned U.S. Patent Publication 20050212072 which is incorporated herein by reference.

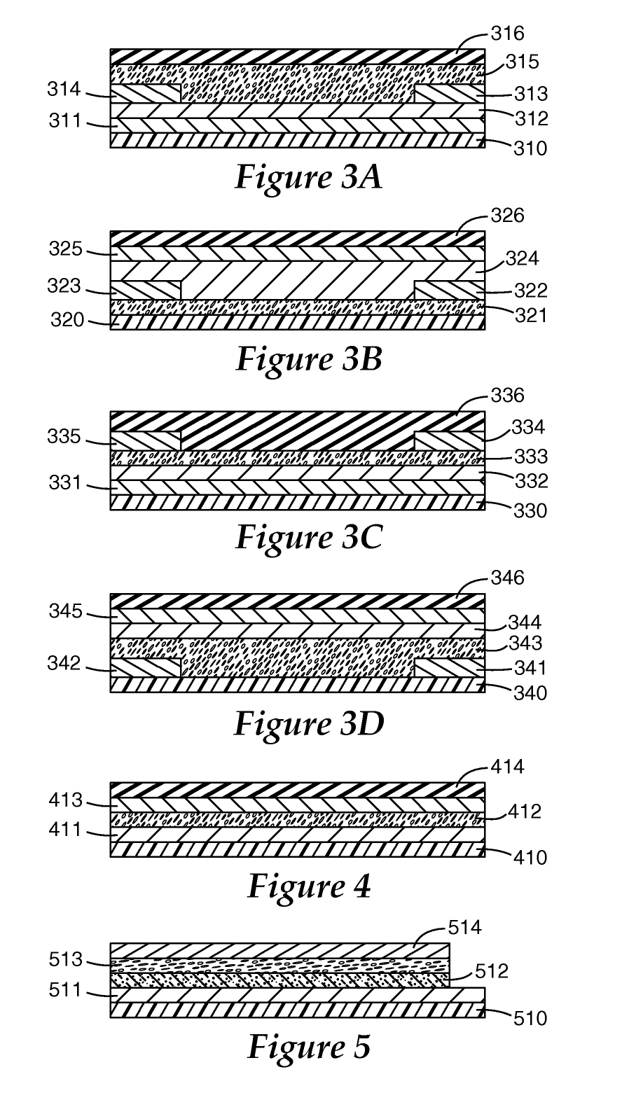

The devices illustrated in FIGS. 3-6 provide examples of devices that may be formed using the fabrication methods described herein. These examples do not provide an exhaustive list of electronic devices that may be formed by these methods. Extrapolation of the methods and systems described using these examples to other types of devices will be readily apparent to those skilled in the art.

An electronic device fabricated by the methods and systems described herein has multiple overlapping layers and at least one of the layers of the electronic device is an electronically or optically active layer. Other layers of the electronic device may include, for example, conductive layers, resistive layers, dielectric layers, adhesion promoting layers, diffusion prevention layers, hole transport layers, electron transport layers, and/or other types of layers known in the art used to fabricate multilayered electronic devices. Various surface processing techniques, such as plasma or corona processing may be applied between the deposition stages.

During fabrication of the electronic devices, registration is maintained between at least two of the electronic device layers. Registration between some layers of the device may not be required. For example, some layers of the electronic devices may be unpatterned layers that do not require registration.

All the layers of the electronic devices need not be deposited using the processes described herein. For example, some layers of the electronic devices may be formed on the substrate by other processes. In one example, a first layer is deposited by another process such as photolithography or ink jet printing. After formation of the first layer, the substrate may be delivered to a deposition system configured according to embodiments of the invention. At this deposition system, one or more additional layers of the electronic devices are deposited as described herein, where the deposition system maintains registration between the previously deposited first layer and the one or more additional layers.

The process of forming the electronic devices may be substantially continuous or may be discontinuous. For example, in one scenario, electronic devices are formed on the substrate in a substantially continuous manner, starting with an input substrate roll that progresses through a series of deposition stations and ending with an output roll that includes the substrate with the layered electronic devices deposited thereon.

After deposition of one or more layers, the substrate roll may be removed from the deposition system. The substrate roll may comprise a subassembly roll good that is ready for additional processing. The additional processing may include additional device or circuit layers deposited in accordance with the approaches of the present invention or by another type of deposition system.

Electronic devices that may be fabricated using the processing methods exemplified by embodiments of the invention include various types of transistors, diodes, photovoltaic devices, light emitting devices, capacitors, stacked electronic devices, and/or other devices. Connections may be made between two or more of the devices deposited on the substrate to form an electric circuit.

FIGS. 3A-3D are cross sectional views of thin film transistors (TFTs) that may be fabricated using the deposition system of FIG. 2. The TFTs described herein illustrate transistor embodiments in which one or more of the layers are deposited using a fabrication process employing aperture masks. Typically, TFTs are based on inorganic semiconductors such as amorphous silicon or cadmium selenide. More recently, organic semiconductor materials have been used to form TFTs. The fabrication processes described herein are particularly advantageous for formation of electronic devices and circuits incorporating organic materials which are not typically amenable to etching processes or photolithography.

FIG. 3A illustrates a cross sectional view of a bottom gate, bottom contact TFT. A pattern of conductive material forming a gate contact 311 is deposited on the substrate 310 at a first deposition station. In one embodiment, the gate material is gold having a thickness of about 60 nm. The metal layers can be deposited by vacuum evaporation, sputtering, or other methods.

Dielectric material 312 is patterned over the gate metal 311 at a second deposition station. In one implementation, the dielectric material 312 comprises aluminum oxide and is deposited with a thickness of about 150 nm. In other embodiments the dielectric may comprise silicon dioxide, mixtures of oxides and nitrides of silicon and aluminum, diamond-like glass, and/or other oxides or dielectrics. The dielectric layer may be deposited by vacuum evaporation, sputtering, plasma enhanced chemical vapor deposition (PECVD) or by other methods.

At a third deposition station, a pattern of conductive material, such as gold, is deposited over the dielectric layer 312 forming source and drain contacts 313, 314. A semiconductor material 315 is deposited at a fourth deposition station over the source and drain contacts 313, 314. The semiconductor may comprise, for example, a zinc oxide or pentacene layer deposited in vacuum by evaporation. Optionally, at a fifth deposition station, an encapsulant 316 is deposited over the semiconductor layer 315 of the TFT.

FIG. 3B illustrates a cross sectional view of a top gate, top contact TFT that may be fabricated in a process using processes in accordance with embodiments of the invention. A semiconductor material 321 is patterned on the substrate 320 at a first deposition station. Drain and source contacts 322, 323 are formed by a pattern of conductive material deposited over the semiconductor layer 321 at a second deposition station. At a third deposition station, a dielectric material 324 is deposited over the source and drain contacts 322, 323. A gate contact 325 is formed by a pattern of conductive material deposited at a fourth deposition station. Optionally, at a fifth deposition station, an encapsulant 326 is deposited over the gate contact 325 of the TFT.

FIG. 3C provides a cross sectional view of a bottom gate top contact TFT that may be fabricated in accordance with embodiments of the invention. A pattern of conductive material deposited at a first deposition station forms a gate contact 331 on the substrate 330. Dielectric material 332 is patterned over the gate contact 331 at a second deposition station. At a third deposition station, a pattern of semiconductor material 333 is patterned over the dielectric 332. A pattern of conductive material is deposited over the semiconductor layer 333 forming source and drain contacts 334, 335 at a fourth deposition station. Optionally, at a fifth deposition station, an encapsulant 336 is deposited over the source and drain contacts 334, 335 of the TFT.

A cross sectional view of a top gate, bottom contact TFT that may be fabricated using the methods described herein is illustrated in FIG. 3D. A pattern of conductive material forming drain and source contacts 341, 342 on the substrate 340 is deposited at a first deposition station. A semiconductor material 343 is patterned over the source and drain contacts 341, 342 at a second deposition station. At a third deposition station, a pattern of dielectric material 344 is deposited over the semiconductor layer 343. A conductive material, deposited in a pattern at a fourth deposition station forms the gate contact 345. Optionally, at a fifth deposition station, an encapsulant layer 346 is deposited over the gate 345 of the TFT.

In some embodiments, the fabrication processes described herein may be used to make light emitting diodes (LEDs) or photovoltaic (PV) cells. In various implementations, the active material of the LEDs or PV cells may be an organic or inorganic semiconductor. PV cells and LEDs have common components such as an anode, a cathode, and an active organic or inorganic material positioned between the anode and cathode. In a PV cell, exposure of the active layer to light causes current to flow between the anode and cathode electrodes. Current flowing between the electrodes of an LED produces light through recombination of electrons and holes in the optically active material.

FIG. 4 depicts a cross sectional view of a PV cell that may be fabricated using the deposition processes described herein. An anode contact 411 is patterned on the substrate 410 at a first deposition station. The active layer 412, e.g., organic or inorganic semiconductor layer, is deposited over the anode contact 411 at a second deposition station. At the third deposition station, the cathode contact 413 is added. Optionally, an encapsulant layer 414 is deposited over the cathode 413 at a fourth deposition station. As will be clear to those skilled in the art, the deposition sequence of the anode and cathode layers may be reversed so that the cathode is deposited at the first deposition station and the anode is deposited at the third deposition station.

Schottky diodes may be fabricated in accordance with the processes described herein. Schottky diodes are formed by a rectifying metal-semiconductor junction. Typically a Schottky diode includes a semiconductor sandwiched between two metals. One metal forms a rectifying contact to the semiconductor and the other metal provides an ohmic contact to the semiconductor. In certain applications, an organic semiconductor may be used. A doped buffer layer between the organic semiconductor and the ohmic contact advantageously increases the magnitude of the breakdown voltage of the device.

FIG. 5 illustrates a Schottky diode that may be fabricated via a process in accordance with embodiments of the invention. An ohmic contact 511 is patterned on the substrate 510 at a first deposition station. At a second deposition station, the doped buffer layer 512 is deposited over the ohmic contact material 511. An organic or inorganic semiconductor 513 is deposited over the doped buffer layer 512 at the third deposition station. At the fourth deposition station, the rectifying contact 514 is added. Optionally, an encapsulant layer (not shown) may be deposited over the rectifying contact 514 at a fifth deposition station.

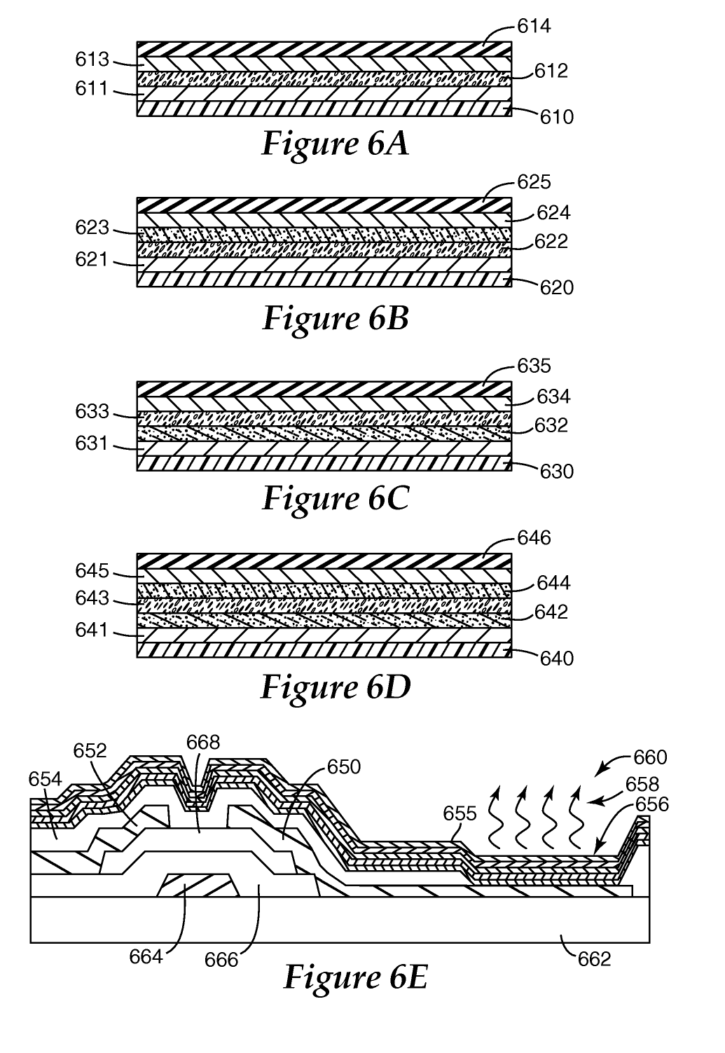

FIGS. 6A-6D illustrate various configurations of LED devices incorporating an organic active layer (OLEDs) that may be formed using the fabrication processes described herein. The optically active light emitter material used in forming the OLEDs may comprise organic materials including small molecule or polymeric materials, for example.

FIG. 6A illustrates a cross sectional view of an OLED that may be fabricated using the deposition processes described herein. An anode contact 611 is patterned on the substrate 610 at a first deposition station. The active layer 612, e.g., organic light emitter, is deposited over the anode contact 611 at a second deposition station. At the third deposition station, the cathode contact 613 is added. Optionally, an encapsulant layer 614 is deposited over the cathode 613 at a fourth deposition station. As will be clear to those skilled in the art, the deposition sequence of the anode and cathode layers may be reversed so that the cathode is deposited at the first deposition station and the anode is deposited at the third deposition station.

OLEDs may use hole and/or electron transport layers in addition to the light emitter material. The hole transport layer facilitates the injection of holes from the anode into the device and their migration towards the recombination zone in the light emitter. The electron transport layer facilitates the injection of electrons from the cathode into the device and their migration towards the recombination zone.

FIG. 6B illustrates an OLED that may be fabricated according to the processes discussed herein. The OLED of FIG. 6B includes an electron transport layer. An anode contact 621 is patterned on the substrate 620 at a first deposition station. The active light emitter material 622 is deposited over the anode contact 621 at a second deposition station. At the third deposition station, electron transport material 623 is deposited over the light emitter 622. At the fourth deposition station, the cathode contact 624 is added. Optionally, an encapsulant layer 625 is deposited over the cathode 623 at a fifth deposition station.

An OLED incorporating a hole transport layer is illustrated in the cross sectional view of FIG. 6C. Fabrication of the OLED involves deposition of an anode contact 631 on the substrate 630 at a first deposition station. At a second deposition station, hole transport material 632 is deposited over the anode 631. The active light emitter material 633 is deposited over the hole transport material 632 at a third deposition station. At the fourth deposition station, the cathode contact 634 is added. Optionally, an encapsulant layer 635 is deposited over the cathode 634 at a fifth deposition station.

FIG. 6D illustrates an OLED incorporating both hole and electron transport layers which may be fabricated by processes described herein. Materials useful in the formation of hole and electron transport layers are described above. An anode contact 641 is patterned on the substrate 640 at a first deposition station. At a second deposition station, hole transport material 642 is deposited over the anode 641. The active light emitter material 643 is deposited over the hole transport material 642 at a third deposition station. At the fourth deposition station, electron transport material 644 is deposited over the light emitter 643. At the fifth deposition station, the cathode contact 645 is added. Optionally, an encapsulant layer 646 is deposited over the cathode 645 at a sixth deposition station.

Fabrication of the layered electronic devices may involve the formation of stacked electronic devices. For example, a light emitting device, such as an OLED may be stacked on a TFT, or vice versa. In one configuration, the input web for the OLED deposition comprises a substrate having a previously deposited thin film transistor and fiducials.

One example where stacked electronic devices are particularly useful is in the fabrication of display backplanes. The example of FIG. 6E shows the deposition of the pixel TFT and OLED on a common substrate 662. In this example, the OLED is top emitting (i.e., emits away from rather than through the substrate). A gate electrode 664, constructed of materials such as titanium and gold, is directly patterned onto the substrate 662 and then a gate dielectric 666, such as SiO₂ or Al₂O₃ is patterned on the gate electrode 664 to entirely isolate the gate electrode 664 from the semiconductor channel 668. The semiconductor channel 668 is a layer of ZnO that is patterned on the gate dielectric 666.

A drain electrode 652, constructed of materials such as aluminum, is patterned on one side of the channel 668 while a separate source electrode 650 is patterned on the other side of the channel 668 and may be constructed of the same material as the drain electrode 652. The source electrode 650 extends onto the substrate 662 and is positioned between the substrate 662 and the OLED stack 656. An encapsulant layer 654, constructed of materials such as a photoimageable epoxy or other material such as SiO₂, is patterned over the layers of the TFT including the source/drain electrodes 650, 652 and the channel 668 while leaving a void above the area of the source electrode 650 where the OLED stack 656 is patterned. It should be noted that the use of the terms source and drain are somewhat arbitrary as it will be appreciated that the electrode contacting the OLED stack 656 may be either the source or the drain, depending upon the circuit design that is chosen.

The OLED stack 656 is constructed of a stack of organic materials. For example, The OLED stack may include a layer of 4,4′,4″-tris(N-(3-methylphenyl)-N-phenylamine)triphenylamine (MTDATA) doped with 3% fluorinated tetracyanoquinodimethane (TCNQ), followed by a layer of N,N′-Bis(naphthalen-1-yl)-N,N′-bis(phenyl)benzidine (NPB), a layer of tris-(8-hydroxyquinoline) aluminum (Alq₃) doped with 10-(2-benzothiazolyl)-1,1,7,7-tetramethyl-2,3,6,7-tetrahydro-1H,5H,11H benzopyrano (6,7,8-ij) quinolizin-11-one (C545T), a layer of Alq₃, a layer of lithium fluoride, a layer of aluminum, and finally a layer of silver.

To complete a path for current through the OLED stack 656, a top electrode 655 is patterned over the top of the OLED stack 656. This top electrode 655 is constructed of a transparent material such as indium tin oxide (ITO) or a thin metal layer so that the light may be emitted through the electrode 655.

Prior to beginning the deposition of the layers of the electronic devices, a pattern of fiducial markings may be deposited onto the substrate. The fiducials may then be used in subsequent stages to properly align the substrate with a mask of the subsequent stage to achieve registration tolerance on the order of microns. Alignment of the substrate having at least one layer of an electronic device formed thereon with an aperture mask of a deposition station used to deposit a subsequent layer is necessary to provide adequate registration between layers of the electronic device.

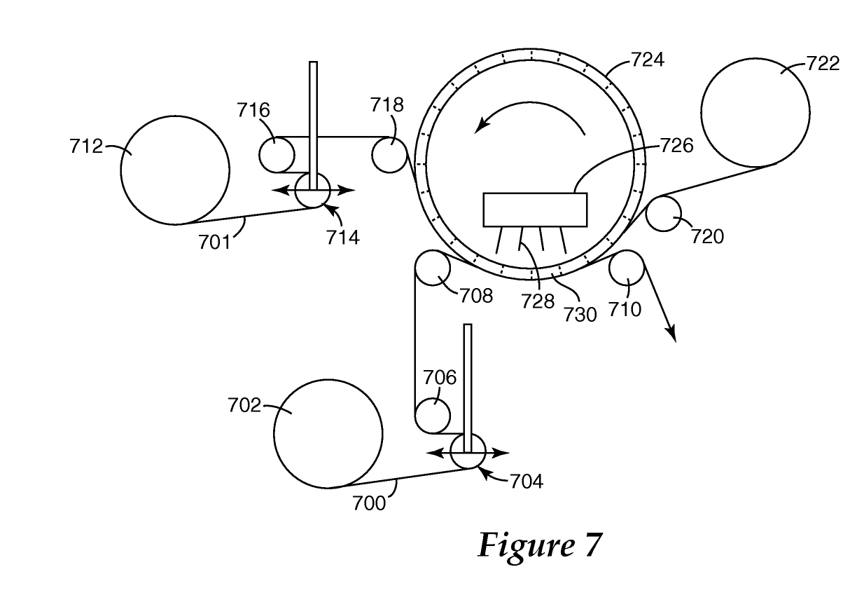

In some embodiments, fiducials may be deposited on the substrate at a first deposition station in a process using an aperture mask and rotating drum as illustrated in FIG. 7. FIG. 7 shows one illustrative embodiment of an apparatus for a deposition station in accordance with one embodiment. At this deposition station, fiducials are applied by depositing material through a mask 701 that includes apertures that provide for the pattern of fiducials. In addition to the fiducials, a first layer of one or more layered electronic devices may also be deposited where that first layer is the same material as that being deposited for the fiducials.

The substrate 700 begins on a roll of a substrate unwind reel 702 which serves as a delivery roller for the substrate 700 to the remainder of the apparatus of this first deposition stage. The substrate 700 is pulled from the reel 702, through a dancer 704, over a tension load cell 706 by a precision drive roller 708. The substrate 700 is pulled over a portion of a circumference of a rotating drum 724 and onto another receiving roller 710 for the substrate 700. The substrate 700 exits the receiving roller 710 and is either pulled into a subsequent deposition station, or is rewound onto a substrate rewind reel.

The dancer 704 and tension load cell 706 are utilized to achieve a pre-determined and controlled elongation, or stretch, of the substrate 700 in the direction of delivery to the drum 724 for a given speed of the substrate 700. The speed of the substrate 700 is dictated by the speed of the precision drive roller 708, which is synchronized closely to the speed of the drum 724, which itself has a precision drive mechanism. The speed chosen is a matter of design choice, based on whether the pre-determined elongation and proper thickness of deposition can be achieved.

As is known in the art, the dancer 704 utilizes a rotary sensor to provide feed back to control the speed of the unwind reel 702, as a tensioning force is applied to the substrate 700 by an actuator of the dancer 704. The tension load cell 706 provides a force reading that can be used to trim the force applied by the actuator of the dancer 704. A control system applies logic based on the readings from the tension load cell 706 and the speed of the drum 724 to make a slight alteration of the speed of the drive roller 708 to control the elongation of the substrate 700 as desired.

The mask 701 begins on a roll of a mask unwind reel 712 which serves as a delivery roller for the mask 701 to the remainder of the apparatus of this first deposition stage. The mask 701 is pulled from the reel 712, through a dancer 714, over a tension load cell 716 by a precision drive roller 718. The mask 701 is pulled tightly over the portion of a circumference of a rotating drum 724 where the substrate is also pulled to thereby bring the mask 701 into close proximity or contact with the substrate 700 and is further pulled onto a receiving roller 720 for the mask 701. The mask 701 exits the receiving roller 720 and is rewound onto a mask rewind reel 722.

As with the substrate 700, the dancer 714 and tension load cell 716 are utilized to achieve a pre-determined and controlled elongation, or stretch, of the mask 701 in the direction of delivery to the drum 724 for a given speed of the mask 701. The speed of the mask 701 is further dictated by the speed of the precision drive roller 718, which is also synchronized closely to the speed of the drum 724. As discussed above in relation to the substrate 700, the speed chosen is a matter of design choice, based on whether the pre-determined elongation and proper thickness of deposition can be achieved.

As with the dancer 704, the dancer 714 utilizes a rotary sensor to provide feed back to the mask unwind reel 712 as a tensioning force is applied to the mask 701 by an actuator of the dancer 714. The tension load cell 716 provides a force reading that can be used to trim the force applied by the actuator of the dancer 714. A control system applies logic based on the readings from the tension load cell 716 and speed of the drum 724 to make a slight alteration of the speed of the drive roller 718 to control the elongation of the mask 701 as desired.

This particular embodiment includes a deposition source 726 that is located internally within the drum 724. Therefore, it is necessary to have the mask 701 be in direct contact with the drum 724 while the substrate 700 is in close proximity or direct contact with the mask 701 and separated from the drum 724 by the mask 701. The drum 724 has large apertures 730 designed into the roll to accommodate material flux towards the mask with little restriction and that are spaced around its circumference to allow deposition material 728 emitted from the deposition source 726 to pass through the drum 724 and reach the mask 701. The apertures in the mask then allow the deposition material 728 to reach the substrate 700 to thereby form the pattern on the substrate 700.

The deposition source 726 may be one of various types depending upon the type of deposition and type of deposition material desired. For example, the deposition source 726 may be a sputtering cathode or magnetron sputtering cathode for purposes of depositing metallic or conductive metal oxide materials, dielectric materials, organic or inorganic semiconductor materials, hole or electron transport materials and/or doped buffer layer materials as previously described. As another example, the deposition source 726 may be an evaporation source for purposes of depositing the above listed materials or other materials.

The configuration of the drum 724, deposition source 726, mask 701, and substrate 700 may be such that the mask 701 and substrate 700 pass on the bottom of the drum with the deposition source 726 emitting the deposition material downward. However, it will be appreciated that the mask 701 and substrate 700 may alternatively be positioned so as to pass over the top of the drum 724 while the deposition source 726 emits the deposition material upward. This alternative is particularly the case where an evaporation source is used.

The substrate 700 and the mask 701 may also be one of various types of materials. Examples include polymeric materials, such as polyester (both PET and PEN), polyimide, polycarbonate, or polystyrene, metal foil materials, such as, stainless steel, other steels, aluminum, copper, or paper or woven or nonwoven fabric materials, all of the above with or without coated surfaces. However, utilizing a material with high elasticity, such as a polymeric material, for the substrate and mask involves precision control of the elongation and for precision registration, as discussed herein, such that the feature size can be made very small. The least dimension of the apertures in a polymeric mask may be on the order of several microns. For example, the least dimension of the aperture may be less than about 100 microns or ranging down to about 2 microns. The corresponding feature that is deposited onto the substrate may have a least dimension that is also on the order of several microns, e.g., less than about 100 microns or ranging down to about 2 microns, with a registration tolerance of ½ the feature size, e.g., less than about 50 microns or ranging down to about 1 micron. Therefore, the density of the electronic devices or other circuitry can be made very high, allowing for high-resolution, small footprint layered device features with accurate registration between device layers. It should be appreciated that if the aspect ratio of a electronic device or circuit feature is large, it may be necessary to deposit the trace by passing the web through two or more deposition stations with two or more successive depositions through offset shadow masks since the aspect ratio of the mask apertures are limited in length of opening before affecting the dimensional stability of the aperture in the polymeric mask. Additional details on fabricating polymer aperture masks related to this embodiment are further described U.S. Pat. No. 6,897,164 (Baude et al.), incorporated herein by reference.

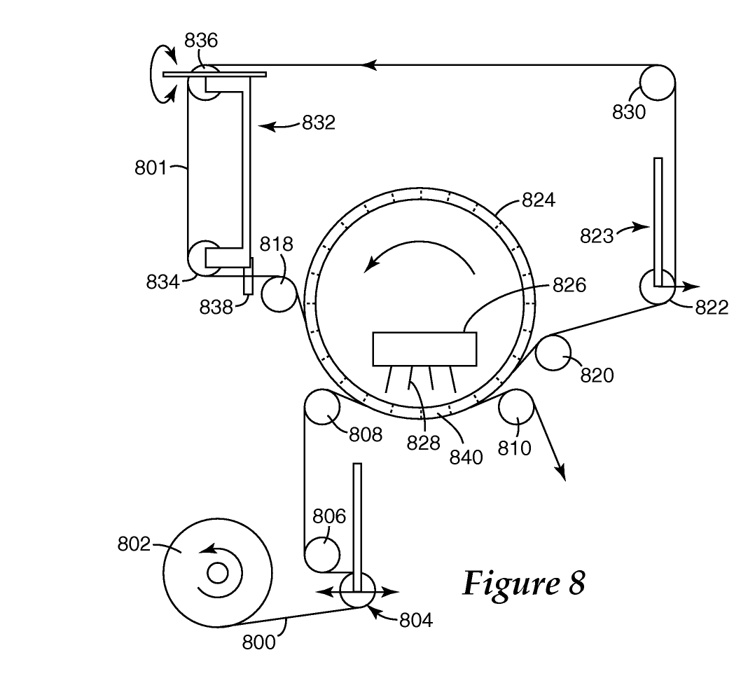

FIG. 8 shows an embodiment like that of FIG. 7 except that the mask is not a roll-to-roll configuration but is instead a continuous loop. Here, the substrate 800 unwinds from reel 802, passed through dancer 804 and over load cell 806 and is pulled by drive roller 808. The substrate 800 passes over the portion of the circumference of the drum 824 and is pulled over receiving roller 810 and then proceeds to the next deposition stage or is rewound onto a rewind reel. Thus, the elongation and speed of the substrate 800 is being controlled as in FIG. 7. Additionally, the deposition source 826 emits material 828 through apertures 840 of the drum 824 and the material reaches a mask 801 and passes through apertures in the mask 801 to reach the substrate 800 as happens in FIG. 7.

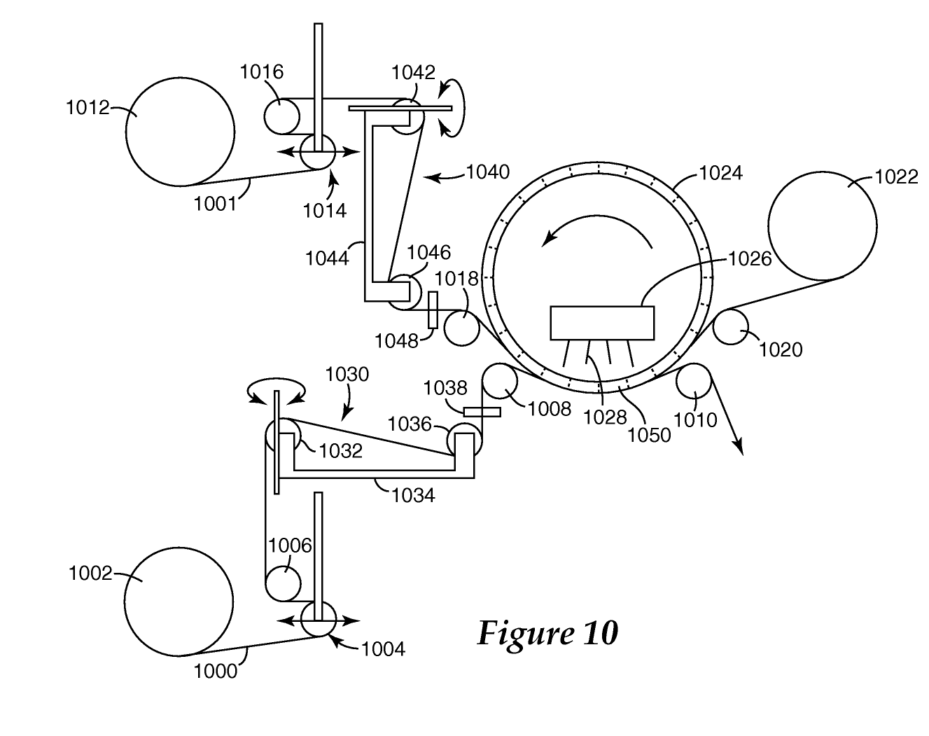

However, the mask 801 is a continuous loop that passes from a tension load cell 834 which is a roller of a web guide 832 and is pulled by drive roller 818 as it passes by a sensor 838. The mask 801 passes over the portion of the circumference of the drum 824 and is pulled away over receiving roller 820. The mask 801 then reaches another receiving roller 822 that is a roller of a tensioner 823 and routes the mask 801 to subsequent receiving roller(s) 830 that then route the mask 801 back to a roller 836 of the web guide 832. In this configuration, the elongation and speed of the mask 801 continues to be controlled by adjusting the force applied by an actuator of the tensioner 823 and the speed of the drive roller 818 based on readings from the tension load cell 834, and the lateral alignment of the mask 801 is also controlled by the web guide 832, where such a web guide is discussed in more detail below in relation to FIG. 10. However, the mask 801 continuously loops so as to be re-used. Eventually, the mask 801 must be replaced or cleaned due to build-up of deposition material 828 onto the mask.

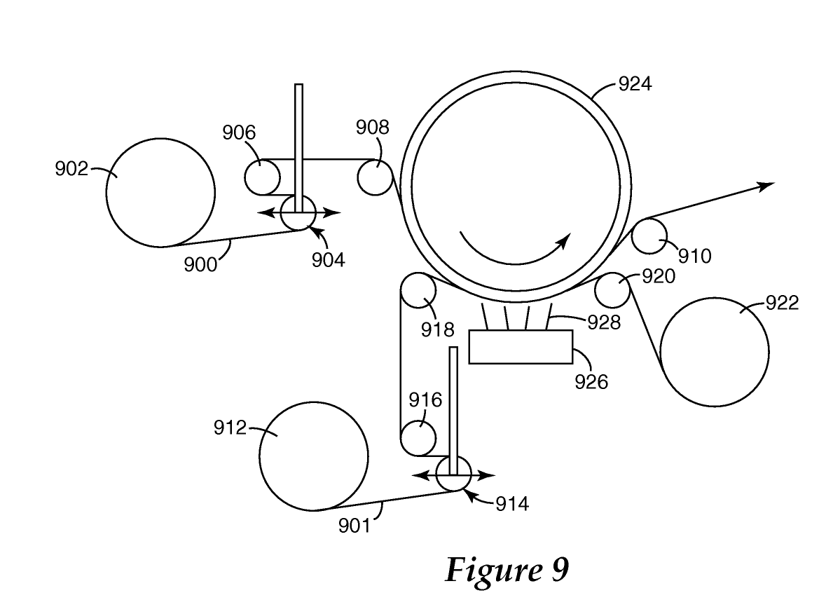

While FIG. 8 shows the configuration like that of FIG. 7 except for the continuously looping mask 801, it will be appreciated that the continuously looping mask 801 as shown in FIG. 8 is equally applicable to the other configurations discussed below in FIGS. 9-12.

FIG. 9 shows an embodiment like that of FIG. 7 except that the deposition source 926 is located outside of the drum 924. Here, the substrate 900 unwinds from reel 902, passes through dancer 904 and over load cell 906 and is pulled by drive roller 908. The substrate 900 passes over the portion of the circumference of the drum 924 and is directed further over receiving roller 910 and then proceeds to the next deposition stage or is rewound onto a rewind reel. Thus, the elongation and speed of the substrate 900 is being controlled as in FIG. 7. Additionally, as happens in FIG. 7, the mask 901 unwinds from reel 912, passes through dancer 914 and over load cell 916 and is pulled by drive roller 918. The mask 901 passes over the portion of the circumference of the drum 924 and is directed further over receiving roller 920 and then is rewound onto a rewind reel 922. Thus, the elongation and speed of the mask 901 is also being controlled as in FIG. 7.

However, the deposition source 926 is located externally of the drum 924 such that the deposition material 928 does not need to pass through the drum 924 prior to reaching the mask 901 and substrate 900. Therefore, the drum 924 need not necessarily include apertures. Additionally, the substrate 900 is in direct contact with the drum 924 while the mask 901 is in close proximity or in direct contact with the substrate 900 with the substrate 900 being positioned between the mask 901 and the drum 924.

While FIG. 9 shows the configuration like that of FIG. 7 except for the deposition source 926 being located externally of the drum 924, it will be appreciated that the external location of the deposition source 926 as shown in FIG. 9 is equally applicable to the other configurations including those of FIG. 8, and FIGS. 10-12.

FIG. 10 shows an embodiment like that of FIG. 7 except that the substrate 1000 already has at least one layer of the electronic devices deposited or otherwise formed thereon. This previously formed layer can be prepared using any process. Since at least one layer is already in place, registration must be maintained between the previously formed layer and the layer being deposited. As described in more detail below, alignment of the aperture mask 1001 with the substrate 1000 during deposition of the subsequently formed layer is used to achieve the registration between layers.

In the embodiment of FIG. 10, the substrate 1000 unwinds from reel 1002, passes through dancer 1004 and over load cell 1006 and is pulled by drive roller 1008. The substrate 1000 passes over the portion of the circumference of the drum 1024 and is directed further over receiving roller 1010 and then proceeds to the next deposition stage or is rewound onto a rewind reel. Thus, the elongation and speed of the substrate 1000 is being controlled as in FIG. 7. Additionally, as happens in FIG. 7, the mask 1001 unwinds from reel 1012, passes through dancer 1014 and over load cell 1016 and is pulled by drive roller 1018. The mask 1001 passes over the portion of the circumference of the drum 1024 and is directed further over receiving roller 1020 and then is rewound onto a rewind reel 1022. Thus, the elongation and speed of the mask 401 is also being controlled as in FIG. 7.

However, there is additional control of the elongation and speed based on sensing the fiducials of both the substrate 1000 and the mask 1001 to maintain the substrate 1000 and mask 1001 in proper alignment in the direction of delivery to the drum 1024. Sensor 1038 senses the fiducials on the substrate 1000 while sensor 1048 senses the fiducials on the mask 1001. The relative speed between the substrate 1000 and mask 1001 may be adjusted via the drive rollers 1008 and 1018 respectively to compensate for the substrate 1000 either leading or lagging the mask 1001.

Furthermore, between the load cell 1006 and the drive roller 1008 for the substrate 1000, a precision web guide 1030 receives the substrate 1000 and controls the transverse (lateral) position of the substrate based on the sensor 1038, sensing the fiducials to determine the transverse position. Moving webs have a tendency to move transversely on the rollers, but in most instances, the transverse position must be maintained within a precise tolerance of at least ½ of the smallest feature dimension at the drum 1024, so the web guide 1030 adjusts the transverse position of the substrate 1000. The web guide 1030 includes a first roller 1032, a frame 1034, and a second roller 1036. The frame 1034 may be pivoted into and out of the page as shown at a pivot point at the edge of first roller 1032 in order to guide the substrate 1000 and change its transverse position on driver roller 1008, and hence on drum 1024. More details about a precision web guide suitable for this purpose can be found in U.S. Patent Application Publication No. 2005/0109811 (Swanson et al.), incorporated herein by reference.

Similarly for the mask 1001, between the load cell 1016 and the drive roller 1018, a precision web guide 1040 receives the mask 1001 and controls the transverse position of the mask 1001 based on the sensor 1048 sensing the fiducials to determine the transverse position. The transverse position of the mask 1001 must also be within a precise tolerance at the drum 1024, so the web guide 1040 adjusts the transverse position of the mask 1001. The web guide 1040 includes a first roller 1042, a frame 1044, and a second roller 1046. The frame 1044 may be pivoted into and out of the page as shown at a pivot point at the edge of first roller 1042 in order to guide the mask 1001 and change its transverse position on driver roller 1018, and hence on drum 1024.

A transverse position control system can be used in conjunction with or can be used independently of an elongation control system. Similarly, an elongation control system can be used in conjunction with or can be used independently of a transverse position control system.

As in FIG. 7, the deposition source 1026 within the drum 1024 emits deposition material 1028 through apertures 1050 of the drum 1024 to reach the mask 1001 and substrate 1000 over the portion of the circumference of the drum 1024. While FIG. 10 has been related to FIG. 7 in terms of this configuration being used as an initial deposition phase, it will be appreciated that the configuration of FIG. 10 may also be used as subsequent phases for situations where the substrate 1000 is not proceeding directly from the preceding deposition phase, but has instead been rewound from the preceding phase and then introduced to this subsequent phase from the unwind reel 1002.

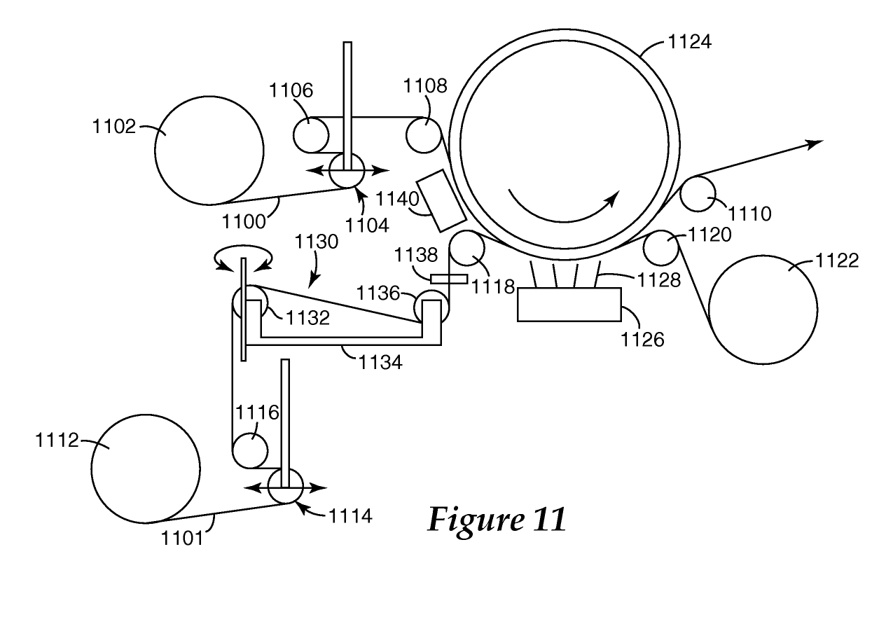

FIG. 11 shows an embodiment like that of FIG. 9 except that the substrate 1100 is provided with fiducials using a fiducial deposition process 1140. The fiducial deposition process 1140 applies the fiducials to the substrate 1100 at a point where the substrate 1100 has come into contact with the circumference of the drum 1124 but prior to the point where the mask 1101 reaches the drum. Since the fiducials are already in place at the drum 1124, precision registration may be maintained between the substrate 1100 and the mask 1101 and the electronic device layer may be deposited during this phase without also simultaneously depositing fiducials of the same material.

In some configurations, the substrate 1100 delivered from reel 1102 may have at least one previously formed electronic device layer disposed thereon. The fiducials deposited by the process 1140 may be used to align the aperture mask 1101 and the substrate 1100 to achieve registration between the at least one previously formed electronic device layer and the electronic device layer being deposited by the deposition station of FIG. 11.

Examples of how the fiducials may be formed onto the substrate by the fiducial deposition process 1140 include sputtering, vapor deposition, laser ablation or laser marking, chemical milling, chemical etching, embossing, scratching, and printing.

In the embodiment of FIG. 11, the substrate 1100 unwinds from reel 1102, passes through dancer 1104 and over load cell 1106 and is pulled by drive roller 1108. The substrate 1100 passes over the portion of the circumference of the drum 1124 including the portion where the fiducial process 1140 is aimed, is directed further over receiving roller 1110, and then proceeds to the next deposition stage or is rewound onto a rewind reel. Thus, the elongation and speed of the substrate 1100 is being controlled as in FIG. 9. Additionally, as happens in FIG. 9, the mask 1101 unwinds from reel 1112, passes through dancer 1114 and over load cell 1116 and is pulled by drive roller 1118. The mask 1101 passes over the portion of the circumference of the drum 1124 and is directed further over receiving roller 1120 and then is rewound onto a rewind reel 1122. Thus, the elongation and speed of the mask 1101 is also being controlled as in FIG. 9.

However, there is additional control of the elongation and speed based on sensing the fiducials of the mask 1101 using sensor 1138 to maintain the mask 1101 in proper alignment in the direction of delivery to the drum 1124 with the fiducial patterning process 1140. The relative speed of the mask 1101 may be adjusted via the drive roller 1118 to compensate for the mask 1101 either leading or lagging the fiducial patterning process 1140.

Furthermore, between the load cell 1116 and the drive roller 1118, a precision web guide 1130 controls within a precise tolerance the transverse position of the mask 1101 based on the sensor 1138 sensing fiducials on the mask 1101 to determine the transverse position. The web guide 1130 includes a first roller 1132, a frame 1134, and a second roller 1136. The frame 1134 may be pivoted into and out of the page as shown at a pivot point at the edge of first roller 1132 in order to guide the mask 1101 and change its transverse position on driver roller 1118, and hence on drum 1124.

As in FIG. 9, the deposition source 1126 located externally of the drum 1124 emits deposition material 1128 to reach the mask 1101 and substrate 1100 over the portion of the circumference of the drum 1124.

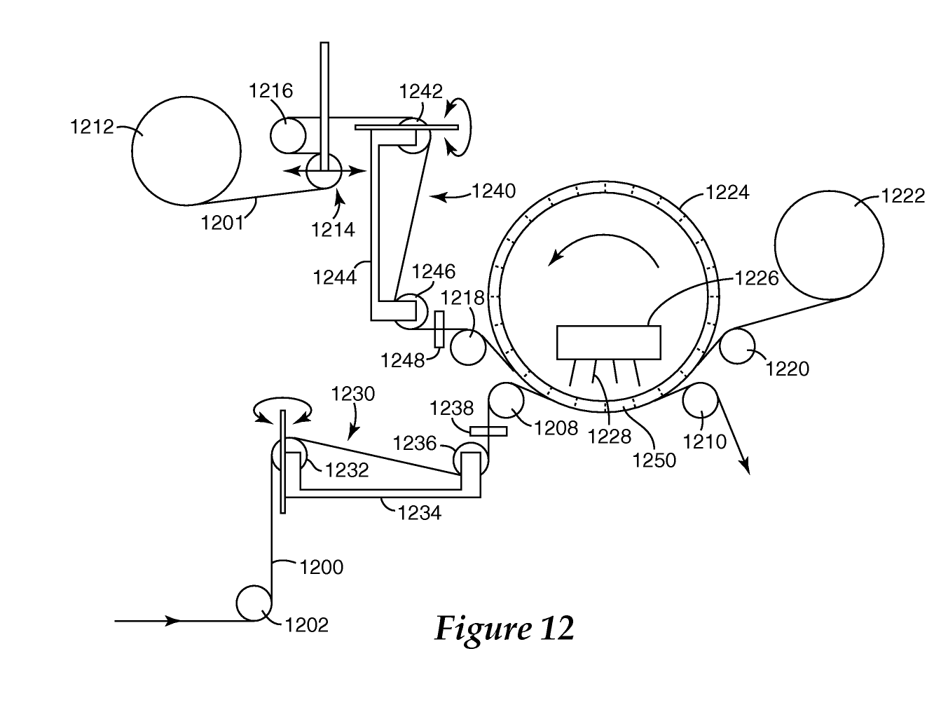

FIG. 12 shows an embodiment like that of FIG. 10 except that the substrate 1200 is being delivered directly from a previous deposition station as opposed to being delivered from an unwind reel. As in FIG. 10, since the fiducials are already in place, alignment may be maintained between the substrate 1200 and the mask 1201 so that the electronic device layers are deposited in registration with at least one previously deposited electronic device layer.

In the embodiment of FIG. 12, the substrate 1200 is received from the preceding phase directly at a tension load cell 1202 and is pulled by drive roller 1208. The substrate 1200 passes over the portion of the circumference of the drum 1224 and is directed further over receiving roller 1210 and then proceeds to the next deposition stage or is rewound onto a rewind reel. There is no dancer for the substrate 1200 for this phase, so the elongation and speed of the substrate 1200 is being controlled by sensing the substrate 1200 tension at load cell 1202 and slightly altering the speed of drive roller 1208 and drum 1224. Further minute adjustments to substrate 1200 elongation can be made by adjusting the relative speed between drive roller 1208 and drum 1224. Additionally, as happens in FIG. 10, the mask 1201 unwinds from reel 1212, passes through dancer 1214 and over load cell 1216 and is pulled by drive roller 1218. The mask 1201 passes over the portion of the circumference of the drum 1224 and is directed further over receiving roller 1220 and then is rewound onto a rewind reel 1222. Thus, the elongation and speed of the mask 1201 is also being controlled as in FIG. 10.

There is additional control of the elongation and speed based on sensing the fiducials of both the substrate 1200 and the mask 1201 to maintain the substrate 1200 and mask 1201 in proper registration in the direction of delivery to the drum 1224. Sensor 1238 senses the fiducials on the substrate 1200 while sensor 1248 senses the fiducials on the mask 1201. The relative speed between the substrate 1200 and mask 1201 may be adjusted via the drive rollers 1208 and 1218 respectively to compensate for the substrate 1200 either leading or lagging the mask 1201.

Furthermore, between the load cell 1202 and the drive roller 1208 for the substrate 1200, a precision web guide 1230 receives the substrate 1200 and controls the transverse position of the substrate based on the sensor 1238 sensing the fiducials to determine the transverse position. The web guide 1230 includes a first roller 1232, a frame 1234, and a second roller 1236. The frame 1234 may be pivoted into and out of the page as shown at a pivot point at the edge of first roller 1232 in order to guide the substrate 1200 and change its transverse position on driver roller 1208, and hence on drum 1224.

Similarly for the mask 1201, between the load cell 1216 and the drive roller 1218, a precision web guide 1240 receives the mask 1201 and controls the transverse position of the mask 1201 based on the sensor 1248 sensing the fiducials to determine the transverse position. The web guide 1240 includes a first roller 1242, a frame 1244, and a second roller 1246. The frame 1244 may be pivoted into and out of the page as shown at a pivot point at the edge of first roller 1242 in order to guide the mask 1201 and change its transverse position on driver roller 1218, and hence on drum 1224.

As in FIG. 10, the deposition source 1226 within the drum 1224 emits deposition material 1228 through apertures 1250 of the drum 1224 to reach the mask 1201 and substrate 1200 over the portion of the circumference of the drum 1224.

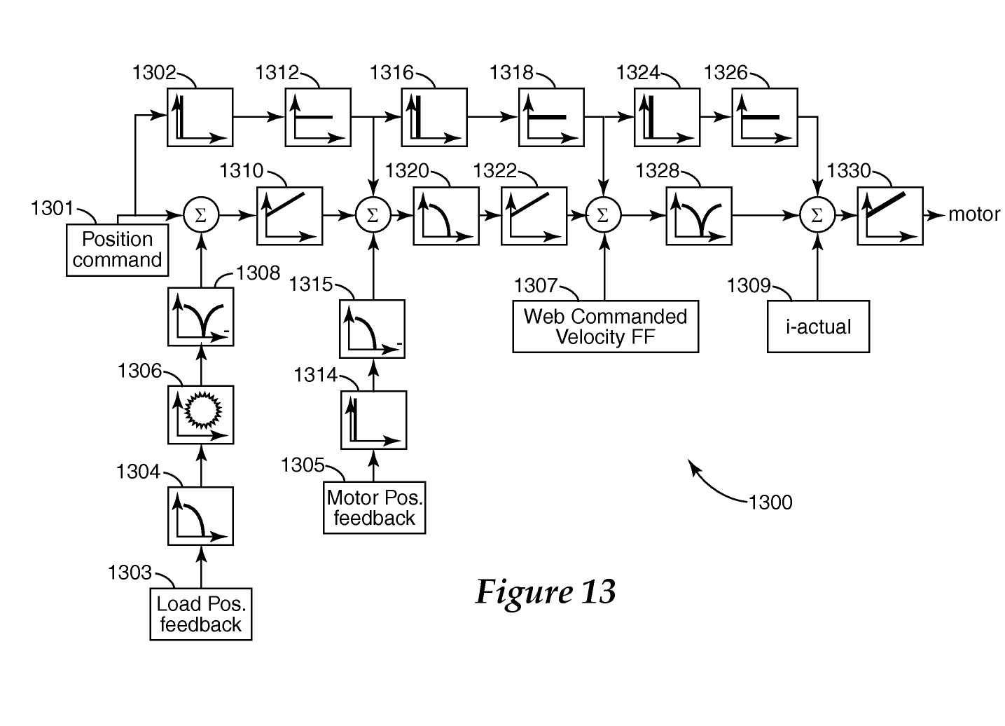

FIG. 13 shows an illustrative rotary motor position and velocity control system 1300 wherein one of the systems 1300 may be used to control the position, velocity and torque applied to each drive roller and drum. The control system 1300 receives a position command 1301 as input, and this command originates from a trajectory generator as can be appreciated from one skilled in the art of motion control. This command is provided to a position feed forward operation 1302 which then outputs the position feed forward signal to a feed forward gain control operation 1312.

The position command 1301 is also summed with another signal that is based on a load position feed back signal 1303 being provided to a low pass filter operation 1304. The load position feed back signal 1303 is received on the basis of a high precision rotary sensor mounted directly on a drive roller or drum. The low pass filter operation 1304 provides an output to observers 1306 that use other internal signals to generate an output that is applied to a feedback filtering operation 1308 to provide the signal that is negatively summed with the position command 1301. This signal is then fed to a position controller 1310 which outputs a signal that is summed with two additional signals.

The feed forward gain signal output by the feed forward gain control operation 1312 is summed with the output signal of the position controller 1310 along with a motor position feed forward feedback signal that is output by position feed forward derivative operation 1314 and is passed through a low pass filter 1315 and that is based upon a received motor position feedback signal 1305. This signal 1305 is received from a high precision rotary sensor mounted on the armature of the motor that is driving a drive roller or drum. The output of the summation is then provided to a low pass filter 1320 whose output is then provided to a velocity controller 1322.

The feed forward gain signal output by the feed forward gain operation 1312 is then provided to a velocity feed forward operation 1316 which provides an output to a feed forward gain operation 1318 to produce a second feed forward gain signal. The second feed forward gain signal is provided to a current feed forward operation 1324 that supplies an output to a feed forward gain operation 1326. Additionally, the second feed forward gain signal is summed with the output of the velocity controller 1322 and from a web commanded velocity feed forward signal 1307 which comes from the trajectory generator. The trajectory generator generates a position reference for each roller's control system, including position and velocity in proper units. The result of summing the velocity feed forward signal 1307 with the output of velocity controller 1322 is passed through notch and other filters 1328 and is summed with the feed forward gain signal as output by the feed forward gain operation 1326 and with the actual motor current measurement 1309 to provide an input to a current controller 1330. The current controller 1330 then outputs a current to the motor that is driving a drive roller or drum.

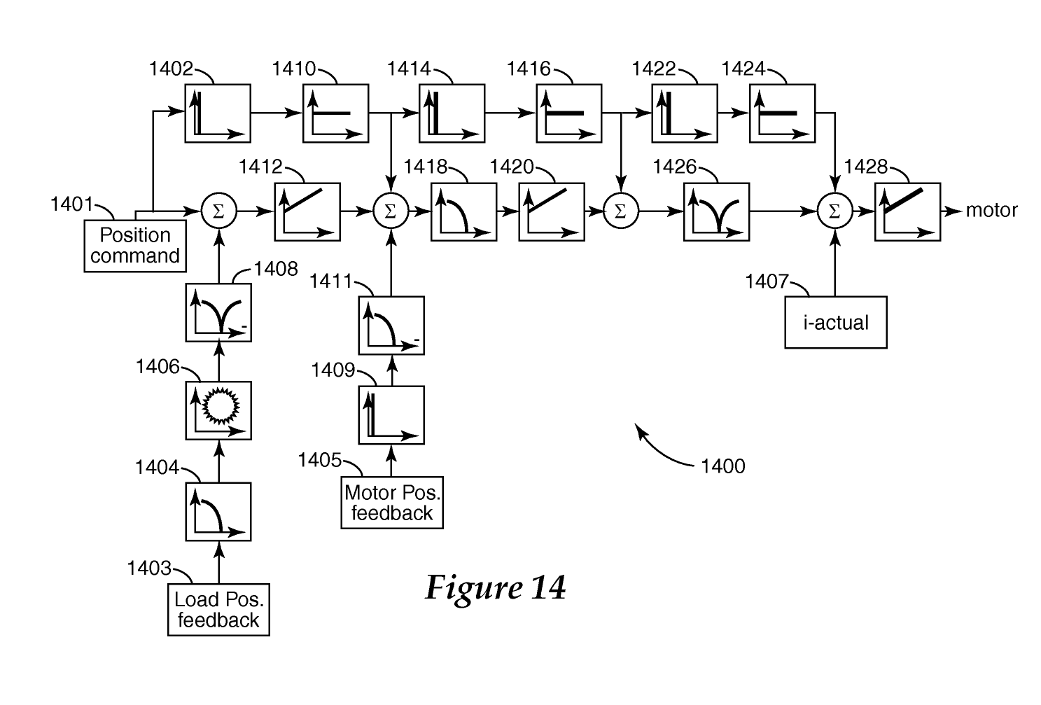

FIG. 14 shows an illustrative guide motor position and velocity control system 1400 wherein one of the systems 1400 may be used to control the lateral position of the substrate while a second one of the systems 1400 may be used to control the lateral position of the mask. The control system 1400 receives a position command 1401 as input, and this command originates from the sensing system that detects the fiducials indicative of lateral position of the web. This command is provided to a position feed forward operation 1402 which then outputs the position feed forward signal to a feed forward gain control operation 1410.

The position command 1401 is also summed with another signal that is based on a load position feed back signal 1403 being provided to a low pass filter operation 1404. The load position feed back signal 1403 is received on the basis of a high precision linear sensor mounted directly on the web guide frame. The feed forward operation 1404 provides an output to observers 1406 that use other internal signals to generate an output that is applied to a feedback filtering operation 1408 to provide the signal that is negatively summed with the position command 1401. This signal is then fed to a position controller 1412 which outputs a signal that is summed with two additional signals discussed below.

The feed forward gain signal output by feed forward gain control operation 1410 is summed with the position controller output signal 1412 along with a motor position feed forward feedback signal that is output by position feed forward derivative operation 1409 and passed through a low pass filter 1411 and that is based upon a received motor position feedback signal 1405. This signal 1405 is received on the basis of a high precision rotary sensor mounted directly on the armature of the motor that is moving the web guide frame. The output of the summation is then provided to a low pass filter 1418 whose output is then provided to a velocity controller 1420.

The feed forward gain signal output by the feed forward gain control operation 1410 is then provided to a velocity feed forward operation 1414 which provides an output to a feed forward gain operation 1416 to produce a second feed forward gain signal. The second feed forward gain signal is provided to a current feed forward operation 1422 that supplies an output to a feed forward gain operation 1424. Additionally, the second feed forward gain signal is summed with the output of the velocity controller 1420. The result is passed through notch and other filters 1426 and is summed with the output of the feed forward gain operation 1424 and the actual motor current measurement 1407 to provide an input to a current controller 1428. The current controller 1428 then outputs a current to the motor that is moving the web guide frame.

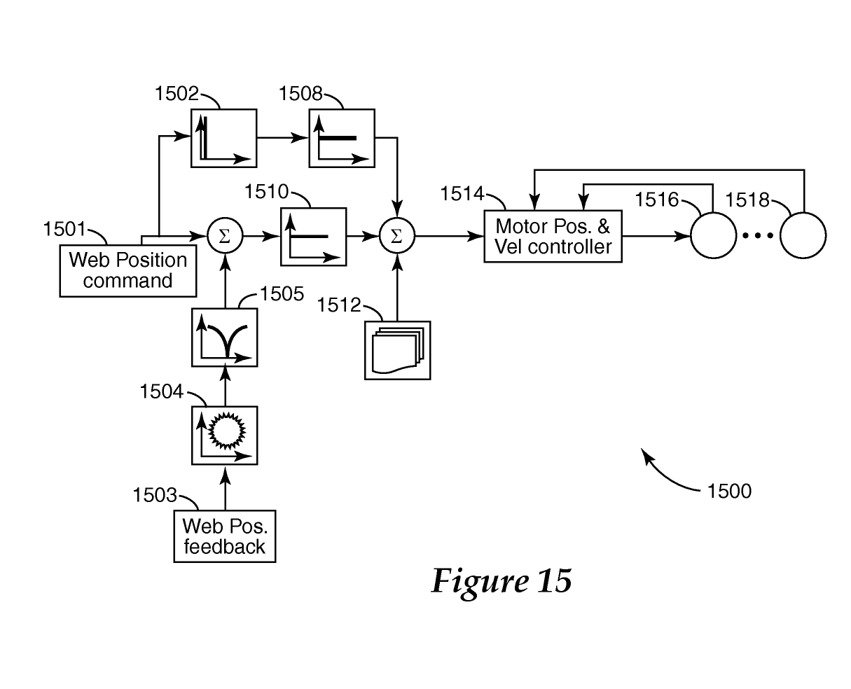

FIG. 15 shows an illustrative web fiducial registration control system 1500 that maintains proper registration between the fiducials of the mask with the fiducials of the substrate for stages of the deposition process where fiducials are already present on both webs, such as shown in FIG. 12. The control system 1500 receives a web position command 1501 as input, and this command originates from a trajectory generator. This command is provided to a position feed forward operation 1502 which then outputs the position feed forward signal to a feed forward gain control operation 1508.

The position command 1501 is also summed with another signal that is based on a web position feed back signal 1503. The web position feed back signal 1503 is received on the basis of the longitudinal web position. This signal can represent the substrate or mask position, or the difference between them. The web position feedback signal 1503 is provided to observers 1504 that enhance the position signal generated by the sensor and whose output is applied to a feedback filtering operation 1505 to provide the signal summed with the position command 1501. The signal resulting from this summation is then fed to a position controller 1510 which outputs a signal that is summed with two additional signals as will be described in the following paragraph.

The feed forward gain signal output by the feed forward gain control operation 1508 is summed with the signal output by the position controller 1510 along with a web feed forward open loop position compensation signal 1512 that comes from the trajectory generator. The output of the summation is a guide position command that is then provided to the web position controller shown in FIG. 13. The motor position and velocity is obtained from the motor 1516 and a corresponding feedback signal 1518 is provided to the motor position and velocity controller 1514. The motor position and velocity controller 1514 includes a sensor position offset compensation with line speed control.

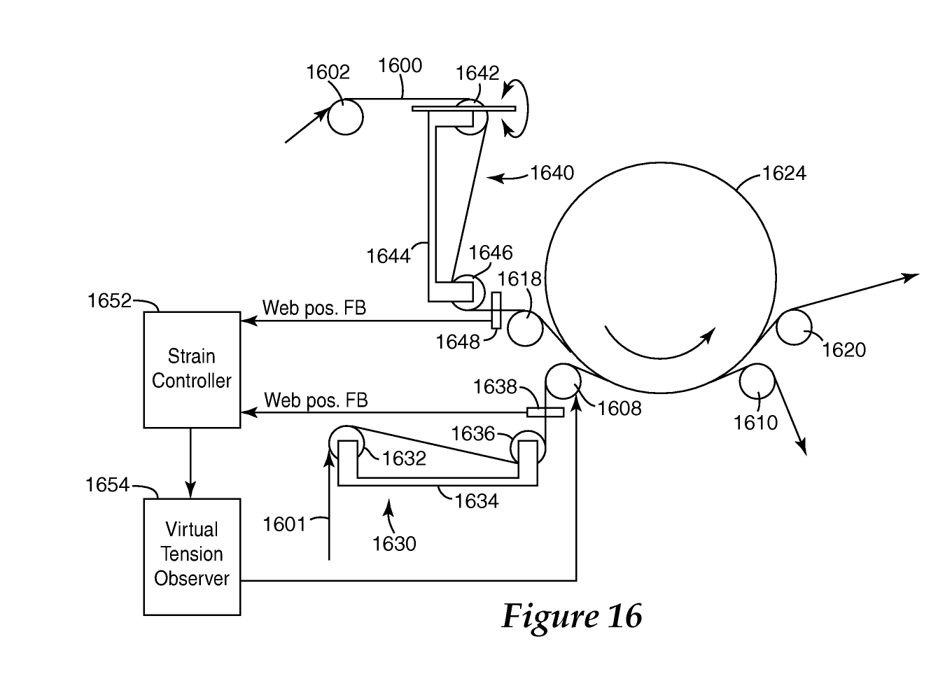

FIG. 16 shows a portion of one illustrative embodiment where the fiducial registration is maintained between the mask and the substrate to allow for the desired feature size of several microns and a registration tolerance of ½ the features size. The substrate 1600 passes by delivery roller 1602 and then passes through web guide 1640 having rollers 1642 and 1646 mounted to frame 1644. Then, the substrate passes by the sensor 1648 that detects the longitudinal and/or lateral web position. The drive roller 1618 makes final corrections to the elongation and velocity of the substrate 1600 as it travels onto the portion of the circumference of the drum 1624 and then exit roller 1620 directs the substrate 1600 on to a next destination.

The mask 1601 enters a web guide 1630 having rollers 1632 and 1636 mounted to a frame 1634. The mask 1601 passes a sensor 1638 that detects the longitudinal and/or lateral web position, and the drive roller 1608 makes final corrections to the elongation and velocity of the mask 1601 as it travels onto the portion of the circumference of the drum 1624 while the exit roller 1610 directs the mask 1601 away from the drum 1624.

During operation, the substrate sensor 1648 and the mask sensor 1638 output web position feedback signals to a strain controller 1652. The strain controller then generates an output signal to a virtual tension observer 1654. A virtual tension observer is a control system technique wherein the value of one variable is estimated based upon known values of other variables. Observers improve control system performance by reducing a variable's measurement lag, increasing its accuracy, or providing the value of a variable that is difficult or impossible to measure directly. The virtual tension observer 1654 then calculates the tension of the webs based on the position feedback provided to the strain controller 1652 and the material parameters for the substrate and the mask, and generates the proper tension setpoints to upstream controllers, as wells as additional corrective position command offsets that may be added to either drive roller. The virtual tension observer is able to estimate changing parameters in real time. Additional details of the virtual tension observer of this embodiment can be found in commonly owned U.S. Patent Application Publication 2005/0137738 A1 which is incorporated herein by reference. The virtual tension observer 1654 then provides a drive signal to the motor of the driver roller 1608.

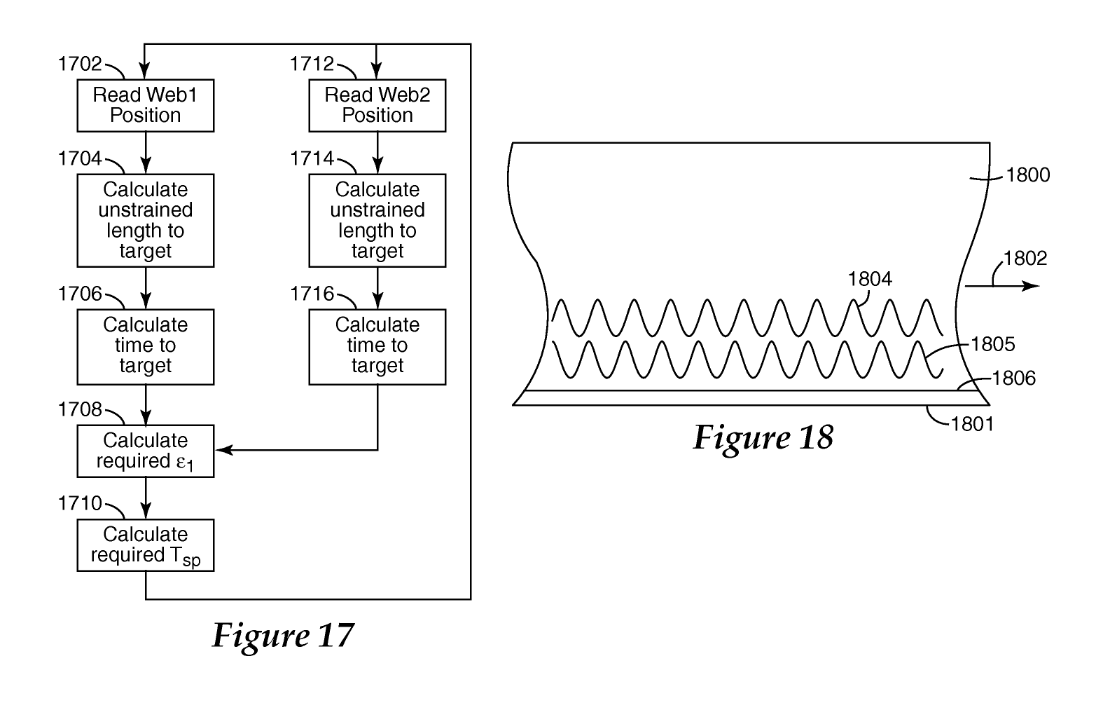

FIG. 17 shows the control loop used by the strain controller 1652 in conjunction with the virtual tension observer 1654. The position of the substrate is read from sensor output at position operation 1702 while the position of the mask is read from sensor output at position operation 1712. The unstrained length to target for the substrate is calculated at calculation operation 1704 while the unstrained length to target for the mask is calculated at calculation operation 1714. The time to target for the substrate is calculated for the substrate at calculation operation 1706 while the time to target for the mask is calculated at calculation operation 1716. Based on the time to target, a new ε₁ value is calculated at calculation operation 1708, where this value represents desired strain in the web. Based on the new ε₁ a required Tₛₚ is calculated at calculation operation 1710, where this value represents the tension required to establish the level of strain.

FIG. 18 shows an example of the fiducial markings that may be located on the substrate and the mask for purposes of controlling the lateral and longitudinal positions and maintaining proper registration between the two webs. As discussed above, these fiducial markings may be pre-patterned or may be added to the web during a stage of the deposition process.

As shown in this example, the lateral or crossweb fiducial may be a line 1806 that is a fixed distance from the deposition patterns to be located on the web 1800. An edge 1801 of the web 1800 may not be located in a precise relationship to the crossweb fiducial line 1806 or any features deposited or formed on the web 1800. From sensing the location of the line 1806 in the lateral direction, it can be determined whether the web 1800 is in the proper location or whether a web guide adjustment is necessary to realign the web in the lateral direction.

As is also shown in this example, the longitudinal or machine direction fiducial marks comprise one or more continuous fiducial marks, such as the sine mark 1804 and cosine mark 1805 illustrated in FIG. 18. Substantially continuous, periodic fiducial marks, such as the sine or cosine marks 1804, 1805 illustrated in FIG. 18 contain information that may be used to determine coarse and fine position of the web. The coarse position may be determined from periodically recurring features of the periodic fiducial marks. In the case of the sine or cosine fiducial marks 1804, 1805 the periodically recurring features used to determine coarse longitudinal position of the web may include the peaks or zero crossings, for example.

In one embodiment, zero crossings for the sine or cosine marks 1804, 1805 are counted for each cycle to determine coarse position. The fine position for each cycle may be determined, for example, by calculating the arctan 2 function of sensor signals corresponding to the sine and cosine marks 1804, 1805. Calculation of the arctan 2 function yields angle and quadrant information that is directly related to the fine position along the web 1800 within the cycle.

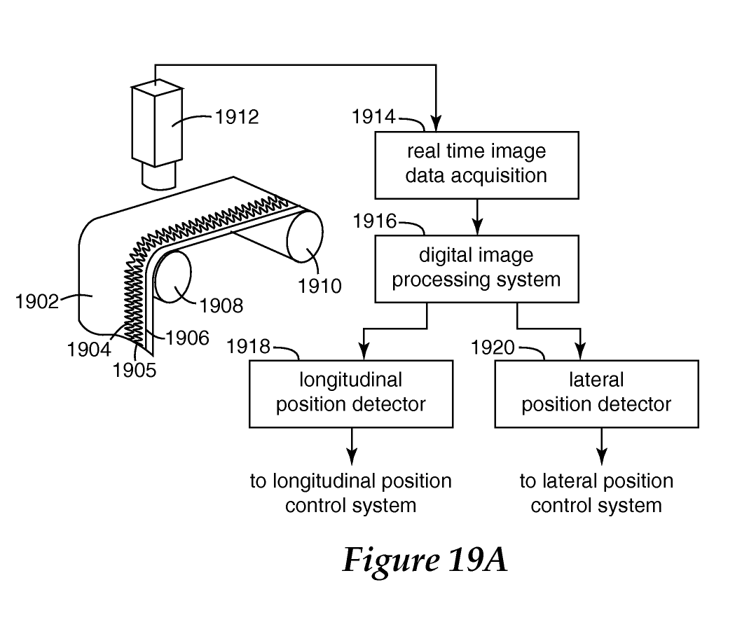

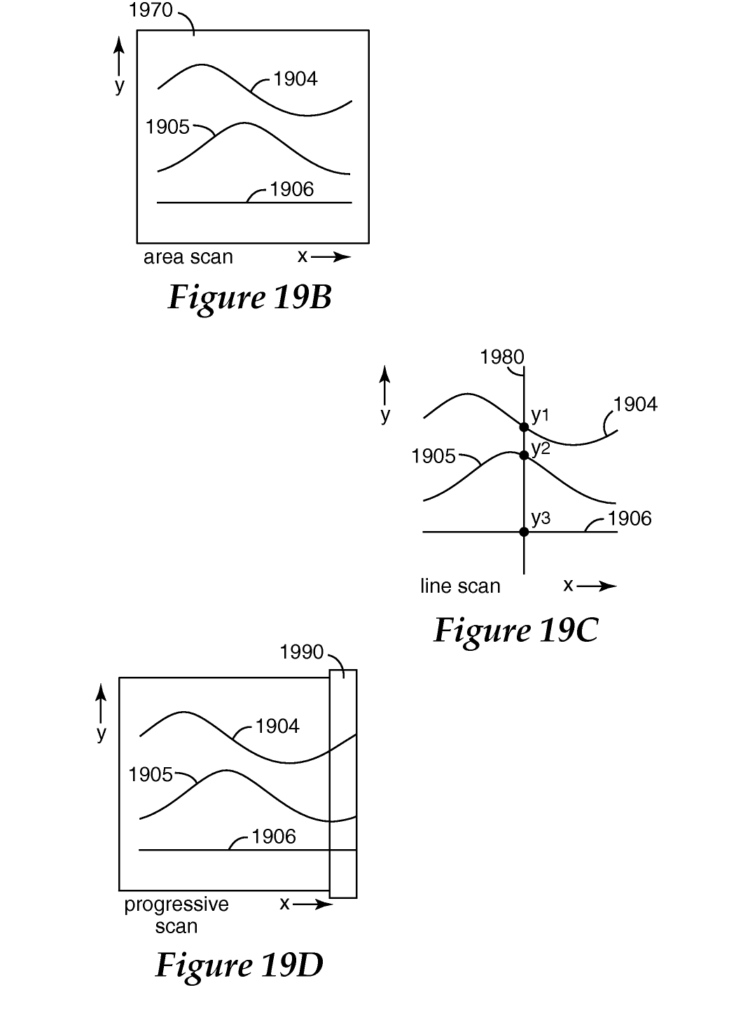

FIG. 19A is a block diagram of a web position detector configured to determine the longitudinal and lateral position of a web in accordance with embodiments of the invention. In this embodiment, a single sensor 1912 is used to sense both longitudinal and lateral fiducial marks 1904-1906. In other configurations, a first sensor may be used to sense a lateral fiducial with a second sensor used to sense the longitudinal fiducial marks.

As illustrated in FIG. 19A, the web 1902 includes longitudinal fiducial marks comprising sine and cosine marks 1904, 1905. The fiducial marks need not be sinusoidal marks, and may be any substantially continuous or piecewise continuous marks that provide information sufficient to achieve the desired registration between electronic device layers.

The web 1902 also has a lateral fiducial mark comprising a horizontal mark 1906. As the web 1902 passes between rollers 1908, 1910, the sensor 1912 senses both the longitudinal fiducial marks 1904, 1905 and the lateral fiducial mark 1906. The sensor 1912 may be camera or other type of optical sensor, electromagnetic sensor, density sensor, contact sensor or any other type of sensor capable of sensing fiducial marks. In the embodiment illustrated in FIG. 19A, the sensor comprises a charge coupled device (CCD) camera.

The output of the camera 1912 is directed to image data acquisition circuitry 1914 that acquires and digitizes the image of the fiducial marks 1904-1906 from the camera 1912. The digital image of the fiducial marks from the image data acquisition circuitry 1914 is directed to a digital image processing system 1916. The digital image processing system 1916 analyzes the image to generate signals corresponding to the sensed fiducial marks. The signals generated by the digital image processing system 1916 may be output to a longitudinal position detector 1918 and optionally to a lateral position detectors 1920. Information from the lateral web position detector 1920 may be used by the longitudinal web position detector 1918 to enhance interpolation of the longitudinal web position. The longitudinal and lateral position determined by the longitudinal web position detector 1918 and the lateral web position detector 1920, respectively, may by output to a movement control system configured to control the longitudinal and lateral position of the web.

FIGS. 19B-19D illustrate examples of the image field of various types of sensors. FIG. 19B shows fiducial marks 1904, 1905, 1906 within the image field 1970 of an area sensor. The area sensor outputs an Xₙ by Yₙ array of values that represent the light intensity of each pixel location. An area sensor provides a large amount of data for signal processing. The large data set allows comparison of the current view with the last view which provides more sophisticated filtering of the data leading to possible advantages in position accuracy, for example. Area sensors provide a slower position update rate when compared to some other types of sensors due to the time it takes to process the relatively larger data set.

FIG. 19C shows fiducial marks 1904, 1905, 1906 within the image field 1980 of a line scan sensor. The line scan sensor outputs a 1 by Yₙ vector of pixel intensity. The line scan sensor provides rapid position updates when compared to the area sensor, but requires data storage of the position history is required.

In FIG. 19D, fiducial marks 1904, 1905, 1906 are shown within the image field 1990 of a progressive scan sensor. Generally, area scan sensors allow the user to select the number of lines to scan, e.g., Xₙ=4 or other number. The progressive scan sensor acquires more data for signal processing than the line scan, but provides slower position updates.

The sine and cosine marks 1904, 1905 may be scaled to achieve maximum resolution. For example, the amplitudes of the marks may be made as large as possible to maximize the marks 1904, 1905 within the image view 1970, 1980, 1990 of the sensor, with some margin to allow for lateral position errors. The longitudinal scaling may be selected based on expected speed of operation. Using a sharper pitch of the sine and cosine marks 1904, 1905 (higher frequency and smaller peak to peak distance) provides steeper slopes, and more resolution in the longitudinal direction. An excessively high pitch can reduce signal to noise ratio and also increases the required sampling rate. The minimum sampling rate requires that no more than ½ cycle passes between samples. However, operation is enhanced when a sampling rate at least 3 to 4 times the minimum sampling rate is used. The achievable sampling rate varies with the type of sensor used, but rates in excess of 1 kHz are possible with camera sensors.

Imperfections in the fiducial marks may be compensated through various signal processing techniques. For example, the sensor signals generated responsive to the marks may be level shifted, filtered, and/or angle adjusted to improve the signal to noise ratio. In some embodiments, improvements in the sensor signals may be achieved by linear or non-linear filtering. For example, if a current web speed is known or estimated, bounds can be placed on the next estimated position update. Any value outside these bounds may be assumed to be noise. In particular, recursive filtering, such as through the use of a Kalman filter, may be used to improve the estimated web position. A Kalman filter uses two or more sources of information and combines them to form the best estimated value based on knowledge of the signals' statistics. The statistics may be generated in real time, or for stationary processes, may be generated offline to reduce the computational burden. Methods and systems for determining longitudinal web position using substantially continuous fiducial marks disposed longitudinally on a web are further described in commonly owned U.S. patent application identified by Attorney Docket No. 62616US002 filed concurrently with the present patent application and incorporated herein by reference.

In another aspect, a method of depositing material forming layered electronic devices is provided using the apparatus described above. The method involves delivering a substrate from a substrate delivery roller while receiving the substrate onto a first substrate receiving roller, wherein the substrate passes in proximity to a portion of a circumference of a first drum when between the substrate delivery roller and the first substrate receiving roller. The method further involves while delivering and receiving the substrate, delivering a first mask from a first mask delivery roller while receiving the first mask onto a first mask receiving roller, wherein the first mask passes in proximity to a portion of a circumference of the first drum when between the first mask delivery roller and the first mask receiving roller and wherein the first mask has a plurality of apertures forming a first pattern and at least a portion of the apertures have a least dimension of about 2 microns. Additionally, the method involves while delivering and receiving the substrate and the first mask, directing a first deposition material from a first deposition source toward a portion of the first mask that is in proximity with the portion of the circumference of the first drum such that a layer of one or more electronic devices is deposited on the substrate.

The method can further involve delivering the substrate from the first substrate receiving roller while receiving the substrate onto a second substrate receiving roller, wherein the substrate passes in proximity with a portion of a circumference of a second drum when between the first substrate receiving roller and the second substrate receiving roller. The method still further involves delivering a second mask from a second mask delivery roller while receiving the second mask onto a second mask receiving roller, wherein the second mask passes in proximity with a portion of a circumference of the second drum when between the second mask delivery roller and the second mask receiving roller and wherein the second mask has a plurality of apertures forming a second pattern. Additionally, the method involves while delivering and receiving the substrate and the second mask, directing a deposition material from a second deposition source toward a portion of the second mask that is in proximity with the portion of the circumference of the second drum such that a second layer of the one or more electronic devices is deposited in registration with the first layer with a registration tolerance of about 1 micron.

The foregoing description of the various embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method of forming one or more electronic devices having multiple overlapping layers on a flexible, elongated substrate, comprising:
moving the flexible substrate through one or more deposition stations, at each deposition station:
moving an elongated aperture mask in relation to a rotating drum, the aperture mask having apertures arranged in a pattern;
aligning the aperture mask and the substrate;
bringing the aperture mask and the substrate into proximity over a portion of a circumference of the rotating drum;
depositing a layer of the layered electronic devices through the apertures of the aperture mask; and
maintaining registration between at least two layers of the layered electronic devices, at least one layer of the layered electronic devices comprising an electronically or optically active material.

2. The method of claim 1, wherein the electronically or optically active material comprises a photovoltaic material, a light emitting material, an inorganic semiconductor material or an organic semiconductor material.

3. The method of claim 1, wherein at least one layer of the layered electronic devices comprises a conductive material that provides electrical contact to the electronically or optically active material layer.

4. The method of claim 1, wherein at least one layer of the layered electronic devices comprises an electron transport material or a hole transport material.

5. The method of claim 1, wherein aligning the aperture mask and the substrate comprises:
aligning one or both of a longitudinal position and a transverse position of the aperture mask over the drum; and
aligning one or both of a longitudinal position and a transverse position of the substrate over the drum of the at least one deposition station.

6. The method of claim 1, further comprising maintaining one or both of a pre-determined elongation of the aperture mask and a pre-determined elongation of the substrate.

7. The method of claim 1, wherein aligning the aperture mask and the substrate comprises:
sensing one or both of fiducials on the aperture mask of at least one deposition station and fiducials on the substrate at the at least one deposition station; and
aligning the aperture mask and the substrate based on the fiducials.

8. The method of claim 1, wherein aligning the aperture mask and the substrate comprises:
sensing one or more substantially continuous fiducials disposed on one or both of the aperture mask and the substrate; and
determining a longitudinal position of one or both of the aperture mask and the substrate based on the substantially continuous fiducials.

9. An apparatus for forming one or more electronic devices having multiple overlapping layers on a flexible, elongated substrate, comprising:
one or more deposition stations, each deposition station comprising:
an elongated aperture mask having apertures arranged in a pattern;
a rotating drum; and
a deposition source configured to emit material toward the substrate through the apertures of the aperture mask to form a layer of the layered electronic devices;
a transport system configured to move the substrate through the one or more deposition stations, at each deposition station the substrate coming into proximity with the aperture mask of the deposition station over a portion of the circumference of the drum; and
an alignment system configured to maintain registration between at least two layers of the layered electronic devices, at least one layer of the layered electronic devices comprising an electronically or optically active material.

10. The apparatus of claim 9, wherein the layered electronic devices comprise one or more of a photovoltaic device, a light emitting device, a diode and a transistor.

11. The apparatus of claim 9, wherein the pattern of apertures in the aperture mask compensates for distortion of the aperture mask during operation of the apparatus.

12. The apparatus of claim 9, wherein at least one deposition station of the one or more deposition stations is configured to deposit the layer comprising the electronically or optically active material.

13. The apparatus of claim 9, wherein the active material comprises a photovoltaic material, a light emitting material, an organic semiconductor or an inorganic semiconductor.

14. The apparatus of claim 9, wherein at least one aperture mask is a polymeric aperture mask.

15. The apparatus of claim 9, wherein the substrate is a polymeric substrate.

16. The apparatus of claim 9, wherein at least one aperture mask includes apertures of less than about 100 microns.

17. The apparatus of claim 9, wherein registration of less than about 50 microns is maintained between the at least two layers of the electronic devices.

18. The apparatus of claim 9 wherein the alignment system is configured to sense a substantially continuous fiducial mark arranged longitudinally on at least one of the aperture mask and the substrate and is further configured to maintain registration between the at least two layers of the layered electronic devices using the fiducial mark.

19. The apparatus of claim 18, wherein the fiducial mark comprises a sinusoidal fiducial mark.

20. The apparatus of claim 9, wherein the transport system is configured to maintain a pre-determined elongation of the aperture mask of the deposition station and to maintain a pre-determined elongation of the substrate.
